(19) United States
(12) Patent Application Publication
(10) Pub. No.: US 2024/0022113 A1
(43) Pub. Date: Jan. 18, 2024

(54) ULTRA-LOW POWER MULTI-PHASE AC LOGIC FAMILY

(71) Applicant: WI-LAN RESEARCH INC., VISTA, CA (US)

(72) Inventors: Rashad Ramzan, Islamabad (PK); Haziq Rohail, Islamabad (PK); Zahid Abbas, Islamabad (PK); Azam Beg, Sacramento, CA (US)

(73) Assignee: WI-LAN RESEARCH INC., VISTA, CA (US)

(21) Appl. No.: 17/812,202

(22) Filed: Jul. 13, 2022

(51) Int. Cl. H02J 50/00; H02J 50/05

(52) U.S. Cl. CPC H02J 50/005; H02J 50/05

(57) ABSTRACT

A set of AC logic circuits that can be powered by AC signals for saving power in microchips. The logic circuits use the relative phases of different AC signals, and a load capacitance to perform digital logic operations in different phases of the AC signals. One phase is used to charge the load capacitor and another phase is used to discharge the capacitor; some of the phases may be just the hold phases to hold the values of the signals. The charging and discharging phases are enabled depending on the input signals and the corresponding expected output of the digital function to be implemented. The circuits can be used in wirelessly powered devices with small number of gates to save power losses associated with the DC rectification. They can be used to perform any kind of combinational gates like NAND, NOR, XOR and also sequential circuits like D Flip flop.

### FIELD OF THE INVENTION

The invention described herein discloses a set of AC powered logic gate circuits for ultra-low power IoT devices.

### BACKGROUND OF THE INVENTION

The present invention discloses a set of AC logic circuits that can be powered up by AC signals; as a result, it saves a significant amount of power in microchips that are used for IoT devices, smart dust, Wireless Power Transfer (WPT) systems, healthcare/biomedical implantations, etc. Such devices should use energy harvesting principles to meet low power requirements. The phenomenon of energy harvesting captures the RF energy available in the atmosphere, or alternatively by powering such devices from a transmitter that sends an RF signal. In either case, the microchip device will have to capture the RF signal to power itself up. The amount of power available in these cases is significantly low, typically in the microwatt and sub-microwatt ranges. Therefore, power is the most critical factor when designing such systems. Furthermore, such systems must also be immune to variations in the input signals' peak-to-peak strength, which is a function of the distance from the source.

DC logic and DC powered circuits are currently being used in a significant majority of devices. However, in the aforementioned ultra-low power IoT devices, rectification in DC circuits is among the significant challenges. Rectifiers and boosters of different types are used in these circuits, which are typically designed using diodes. Diode based rectifiers and booster circuits offer relatively lower efficiency, especially in the case of IoT devices, where the captured AC signal at the input is very weak, with a typical peak-to-peak voltage of a few hundred millivolts. The efficiency of the diode rectifier is very low in this operating region because of the low voltage levels. Therefore, in such cases, a need to eliminate the rectifier and operate the complete system on AC signals exists. Such a novel system of digital logic gates that operate entirely on the AC power, specifically on quadrature RF signals, is disclosed in this application.

### SUMMARY OF THE INVENTION

The present invention discloses a set of AC powered logic gates for applications in wirelessly powered circuits such as IoT devices, smart dust, WPT systems, biomedical implants, etc., where power availability is a limiting factor, as supply voltages are very low. The energy harvesting and resonant circuit transmission-based methods that are used to power such devices can only work on AC/RF signals. Since most of the logic families, sensors, and other circuits, available in the prior art are based on DC, wirelessly powered devices tend to rectify the received RF signals into DC and then use that DC power for their operation. Since the power is limited in these systems, using DC circuits with rectification remains a significant challenge due to the amount of power losses associated with the diode-based rectification. Consequently, a novel family of AC powered logic circuits are disclosed in this application to overcome these challenges. The logic gates disclosed in this invention are AC powered, and hence have the ability to be used to create ultra-low powered processors for wirelessly powered IoT based devices.

In one embodiment, an AC logic gate structured and configured to be powered by three or more AC signals is provided. The three or more AC signals comprise three quadrature AC signals, wherein a complete cycle of the three quadrature AC signals has a plurality of phases. The AC logic gate in this embodiment includes a plurality of transistors, each of a first one or more of the plurality of transistors being structured and configured to receive one or more of the three quadrature AC signals, and each of a second one or more of the plurality of transistors being structured and configured to receive one of a number of input signals. The AC logic gate in this embodiment also includes a capacitance coupled to the plurality of transistors, wherein the capacitance is structured and configured to be pre-charged responsive to a first one of the phases, wherein the capacitance is structured and configured to be discharged responsive to a second one of the phases, and wherein the AC logic gate is structured and configured to, responsive to the number of input signals, generate and output an output signal, wherein a state of the output signal depends on a state of each of the number of input signals.

In another embodiment, a method of performing digital logic operations is provided that includes receiving three quadrature AC signals in a transistor circuit of an AC logic gate to power the AC logic gate, wherein a complete cycle of the three quadrature AC signals has a plurality of phases, receiving a number of input signals in the transistor circuit, pre-charging a capacitance of the AC logic gate responsive to a first one of the phases, the capacitance being coupled to the transistor circuit, discharging the capacitance responsive to a second one of the phases; and responsive to the number of input signals, generating and outputting an output signal from the AC logic gate, wherein a state of the output signal depends on a state of each of the number of input signals.

### BRIEF DESCRIPTION OF THE DRAWINGS

The accompanying drawings, which are incorporated in and constitute part of this specification, illustrate the embodiments of the invention and, together with the description, serve to explain the principles of the invention. The embodiments illustrated herein are presently preferred, it being understood by those skilled in the art, however, that the invention is not limited to the precise arrangements and instrumentalities shown, wherein:

FIG. 1 shows the resonant wireless power receiving circuits, wherein the inductors are used to capture 90° out of phase signals that are called quadrature signals. This embodiment is used when quadrature RF signals outside of the chip are available, i.e., in the case of Resonant Wireless Power Transfer (RWPT).

FIG. 2 shows the resonant wireless power receiving circuit, wherein the inductors are used to produce 180° out of phase AC signals. This embodiment is used when only 180° AC signals are available, i.e., when an external quadrature RF generator is not available or the system requires energy harvesting techniques.

FIG. 3 shows the captured quadrature RF/AC signals that are used to power the logic circuits in some disclosed embodiments of the invention.

FIG. 4 shows the 180° AC signals that are used to power the logic circuits in in some disclosed embodiments of the invention.

FIG. 5 shows an embodiment of the quadrature RF inverter circuit. The power signal VI+ and gate signal VQ+ are 90° out of phase to each other.

FIG. 6 shows the output of the quadrature RF inverter circuit of the embodiment of FIG. 5.

FIG. 7 shows an improved version of the quadrature RF inverter circuit as the preferred embodiment of the invention.

FIG. 8 shows the output of the quadrature RF inverter circuit of the embodiment of FIG. 7.

FIG. 9 shows an 180° AC powered RF inverter circuit. The signal V+ and V− are 180° out of phase.

FIG. 10 shows the output of the AC powered RF inverter circuit of the embodiment of FIG. 9.

FIG. 11 shows an embodiment of the quadrature RF NAND gate.

FIG. 12 shows the output of the quadrature RF NAND gate of the embodiment of FIG. 11.

FIG. 13 shows an improved version of the quadrature RF NAND gate as the preferred embodiment of the invention.

FIG. 14 shows the output of the quadrature RF NAND gate of the embodiment of FIG. 13.

FIG. 15 shows an 180° AC powered RF NAND gate.

FIG. 16 shows the output of the AC powered RF NAND gate of the embodiment of FIG. 15.

FIG. 17 shows an embodiment of the quadrature RF NOR gate.

FIG. 18 shows the output of the quadrature RF NOR gate of the embodiment of FIG. 17.

FIG. 19 shows an improved version of the quadrature RF NOR gate as the preferred embodiment of the invention.

FIG. 20 shows the output of the quadrature RF NOR gate of the embodiment of FIG. 19.

FIG. 21 shows an 180° AC powered RF NOR gate.

FIG. 22 shows the output of the AC powered RF NOR gate of the embodiment of FIG. 21.

FIG. 23 shows an embodiment of the quadrature gated Flip Flop circuit.

FIG. 24 shows the output of the quadrature RF D Flip Flop of the embodiment of FIG. 23

FIG. 25 shows an improved version of the quadrature RF D Flip Flop circuit as the preferred embodiment of the invention.

FIG. 26 shows the output of the quadrature RF D Flip Flop circuit of the embodiment of FIG. 25.

FIG. 27 shows an 180° AC powered RF D Flip Flop.

FIG. 28 shows the output of the AC powered RF D Flip Flop of the embodiment of FIG. 27.

FIG. 29 shows an embodiment of the quadrature RF XOR gate.

FIG. 30 shows the output of the quadrature RF XOR gate of the embodiment of FIG. 29.

FIG. 31 shows an improved version of the quadrature RF XOR gate. The XOR logic is evaluated using two signals IN1_XOR and IN2_XOR and their inverted counterparts IN1_XOR′ and IN2_XOR′.

FIG. 32 shows the output of the improved quadrature RF XOR gate of the embodiment of FIG. 31.

FIG. 33 shows an 180° AC powered RF XOR circuit. The circuit is powered by two 180° out of phase signals V+ and V−.

FIG. 34 shows the output of the 180° AC powered RF XOR circuit of the embodiment of FIG. 33.

FIG. 35 shows an improved version of quadrature RF XOR gate of embodiment of FIG. 29. The XOR logic is evaluated using only two signals IN1_XOR and IN2_XOR.

FIG. 36 shows the output of quadrature RF XOR gate of the embodiment of FIG. 35.

FIG. 37 shows an improved version of quadrature RF XOR gate of the embodiment of FIG. 31. The XOR logic is evaluated using only two signals IN1_XOR and IN2_XOR.

FIG. 38 shows the output of quadrature RF XOR gate of the embodiment of FIG. 37.

FIG. 39 shows an improved version of 180° AC powered RF XOR gate of the embodiment of FIG. 33. The XOR logic is evaluated using only two signals IN1_XOR and IN2_XOR.

FIG. 40 shows the output of 180° AC powered RF XOR gate of the embodiment of FIG. 39.

### DETAILED DESCRIPTION OF THE EMBODIMENTS

The figures and their corresponding embodiments provided in this disclosure are explained in detail for a thorough understanding of the invention and the accompanying embodiments. All such figures are schematic or block diagrams or preferred structures and they are not drawn to the scale. Further, the schematics and block diagrams or structures are drawn to clarify the details of the invention. One skilled in the art can understand that only the core components are shown in the embodiments for better enablement. Hence, any additional elements that would be included in these circuits or structures for implementation are implicitly a part of this disclosure. All embodiments, systems, structures, schematics, circuits, and sub-circuits that utilize the fundamental principles of the invention or have elements of the invention are hereby treated to be under the complete protection of the disclosed invention.

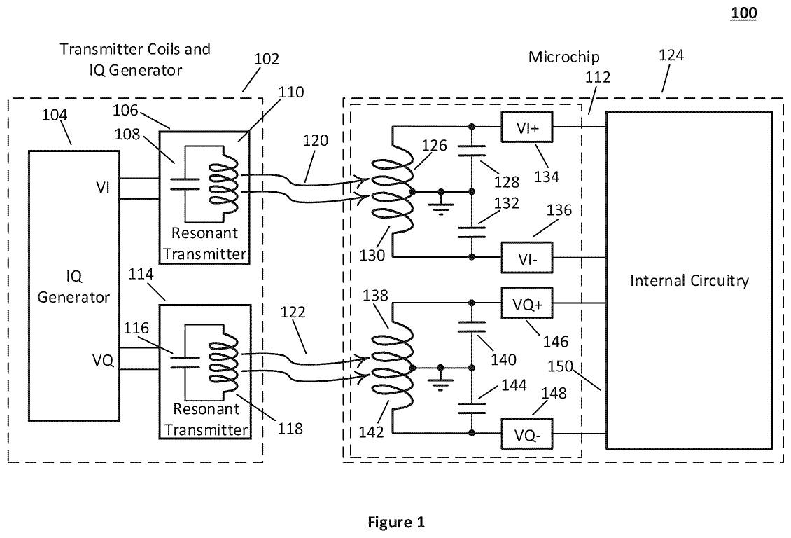

FIG. 1 shows the wireless power receiving circuit of the microchip 124, and the resonant receiver circuit 112 comprising of on-chip inductors 126, 130, 138 and 142, along with capacitors 128, 132, 140 and 144. All of the proposed circuits use three AC signals VI+ 134, VI− 136, and VQ+ 146 for power, and the signal VQ− 148 is included in the Figure only for the sake of completeness and can be omitted in some other embodiments of the invention. The microchip's resonant receiver circuit 112 receives quadrature (IQ) power from the external circuit 102, comprising of IQ generator 104, and resonant transmitters 106 and 114. Resonant transmitters 106 and 114 are comprised of inductors 110 and 118, and capacitors 108 and 116. The quadrature signals generated by 104 are transmitted through RWPT (Resonant Wireless Power Transfer) by resonant transmitters 106 and 114, shown as 120 and 122 which are received by microchip's circuit 112, which is then used by its internal circuitry 150.

In another embodiment of FIG. 1, the inductor 142 and the capacitor 144 can be omitted to only generate three signals VI+ 134, VI− 136, and VQ+ 146.

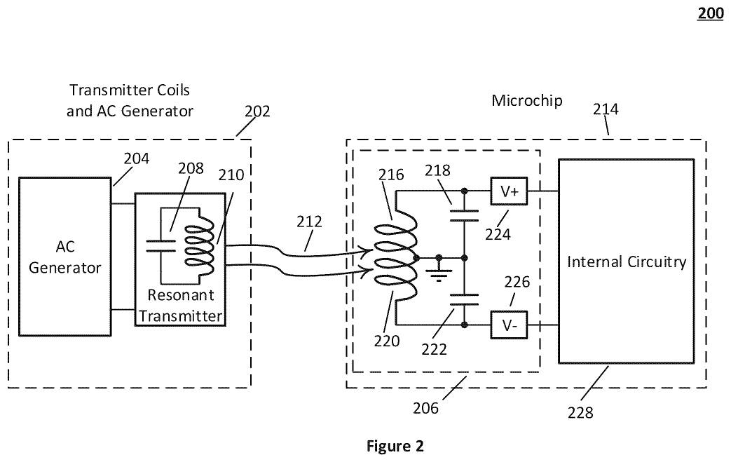

FIG. 2 shows another embodiment of the microchip 214 wherein wireless power receiving circuit 206 only generates 180° signals V+ 224 and V− 226. External circuit 202, comprising of AC generator 204, inductor 210 and capacitor 208, generates and transmits AC signal 212. This signal is captured by the microchip's receiving circuit 206 using inductors 216 and 220, and capacitors 218 and 222, to power internal circuitry 228. Both of the arrangements, i.e., the embodiment of FIG. 1 and that of FIG. 2 can be used with slightly different modifications of proposed AC gates. In the embodiment of FIG. 1, power receiving circuit 112 receives IQ power and generates both I and Q signals. Hence the logic gates used in internal circuitry 150 are also based on IQ. On the other hand, in the embodiment of FIG. 2, power receiving circuit 206 receives 180° AC signals. Therefore, the logic gates used in the internal circuitry 228 only require two 180° out of phase signals for operation.

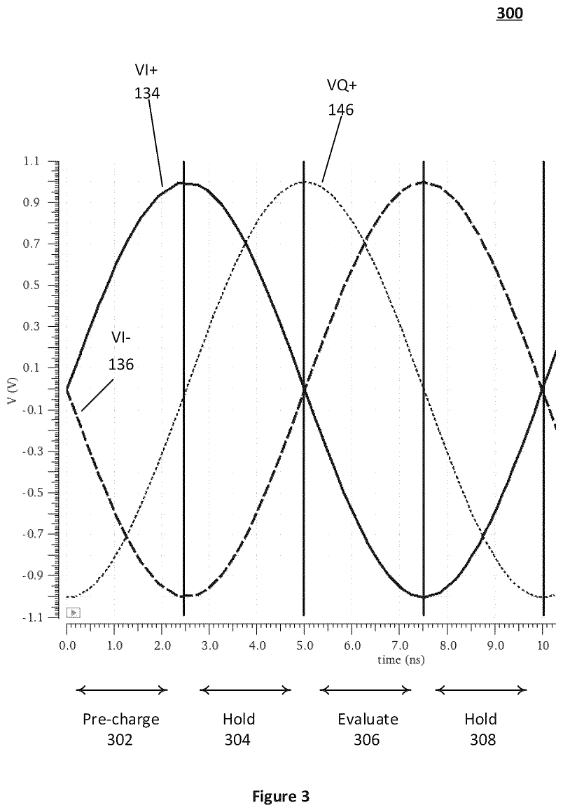

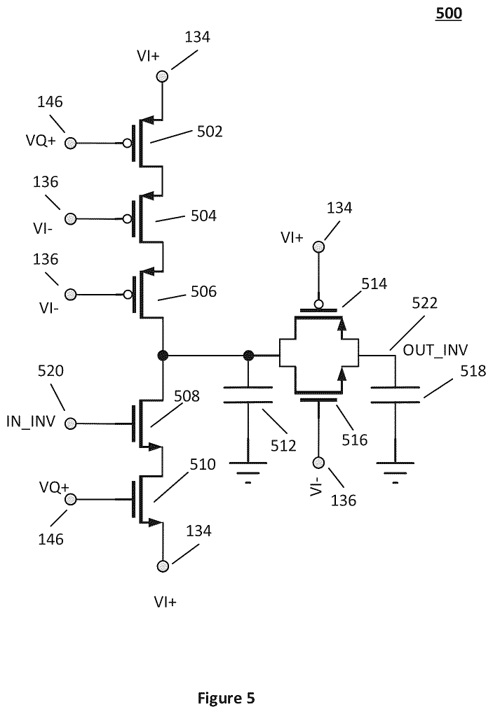

FIG. 3 shows signals VI+ 134, VI− 136, and VQ+ 146 that are used to power the circuits of the embodiments of FIGS. 5, 7, 11, 13, 17, 19, 23, 25, 29, 31, 35 and 37. The signal VQ+ 146 is 90° out of phase from VI+ 134, hence called quadrature, and the signal VI− 136 is 180° out of phase from VI+ 134, and the fourth signal VQ− 148 is not shown here since it is unused. The complete cycle of these AC signals is divided into four distinct phases 302, 304, 306 and 308. The first phase is pre-charge phase 302, the second phase is a hold phase 304, the third phase is evaluate phase 306, and the fourth phase is another hold phase 308. Different transistors operate in different phases to perform the logic operations. The fundamental operating principle of the proposed IQ based logic circuits is derived using these phases.

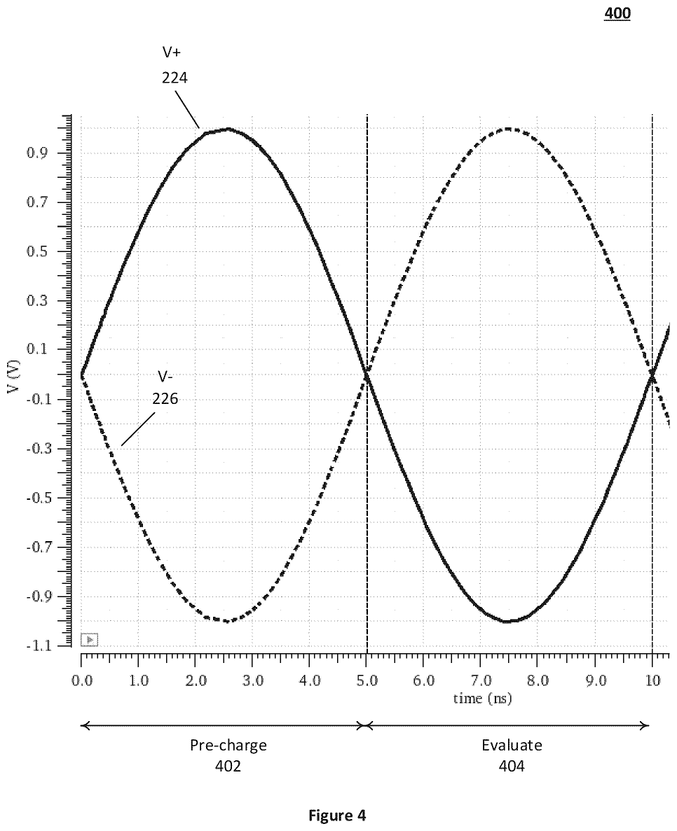

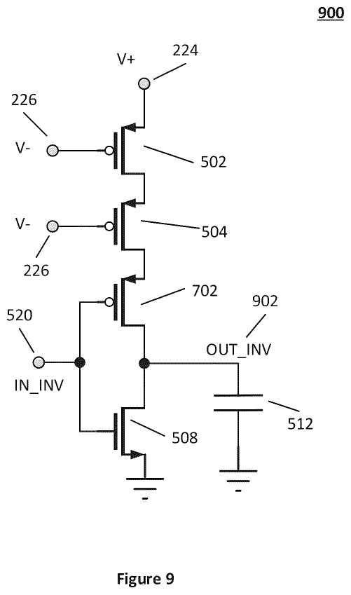

FIG. 4 shows signals V+ 224 and V− 226 that are used to power the circuits of the embodiments of FIGS. 9, 15, 21, 27, 33 and 39. The signal V− 226 is 180° out of phase from V+ 224. Unlike the signals in FIG. 3, the complete signal cycle in FIG. 4 is divided into two phases 402 and 404. The first phase is the pre-charge phase 402; while the second phase is the evaluate phase 404. The fundamental operating principle of the AC circuit of the embodiment of FIGS. 9, 15, 21, 27, 33 and 39 is derived using these two phases.

FIG. 5 shows an embodiment of the IQ based inverter circuit. It is powered using the three signals VI+ 134, VI− 136, and VQ+ 146 generated by the circuit of the embodiment of FIG. 1. The circuit can be divided into two primary branches; the PMOS charging branch and the NMOS discharging branch. The gate to source signals of the transistors are arranged in a manner to ensure that only one branch conducts during each operating phase. Transistors 504 and 506 in this embodiment are always ON due to the 180° nature of VI+ 134 and VI− 136 signals. These transistors are used for isolation to improve the circuit's operation. During the pre-charge phase 302, when VI+ 134 is higher than VQ+ 146, transistor 502 conducts whereas 510 remains cutoff. Thus, the PMOS charging branch conducts irrespective of input signal 520 during this phase and establishes a positive charge on capacitor 512. Capacitor 512 may be included deliberately or it could also be the load capacitance of subsequent circuits driven by the inverter. In both of the hold phases 304 and 308, neither transistor 502 nor transistor 510 gets enough Vsg, or Vgs in case of NMOS; as a consequence, neither of the two branches conducts. During evaluate phase 306, when VQ+ 146 is greater than VI+ 134, transistor 502 is cutoff which disables the PMOS charging branch, whereas, transistor 510 is turned ON which enables the NMOS discharging branch. During this phase, input transistor 508 behaves like an inverter. If input signal IN_INV 520 is high, transistor 508 conducts which discharges capacitor 512 and a 0 (low) output is established. On the flip side, if input signal 520 is low, transistor 508 stays in cutoff which leaves capacitor 512 with a positive voltage that is established previously during pre-charge phase 302. However, in this embodiment, the output signal at capacitor 512 keeps oscillating between high and low states if input signal 520 is high. To resolve this issue, a sample and hold circuit comprising of transistors 514 and 516 is used to sample output signal from 512 only in evaluate phase 306 so as to avoid unnecessary output jumps. Transistors 514 and 516, with gate signals VI+ 134 and VI− 136, serve this purpose together to generate final output OUT_INV 522 at the capacitor 518.

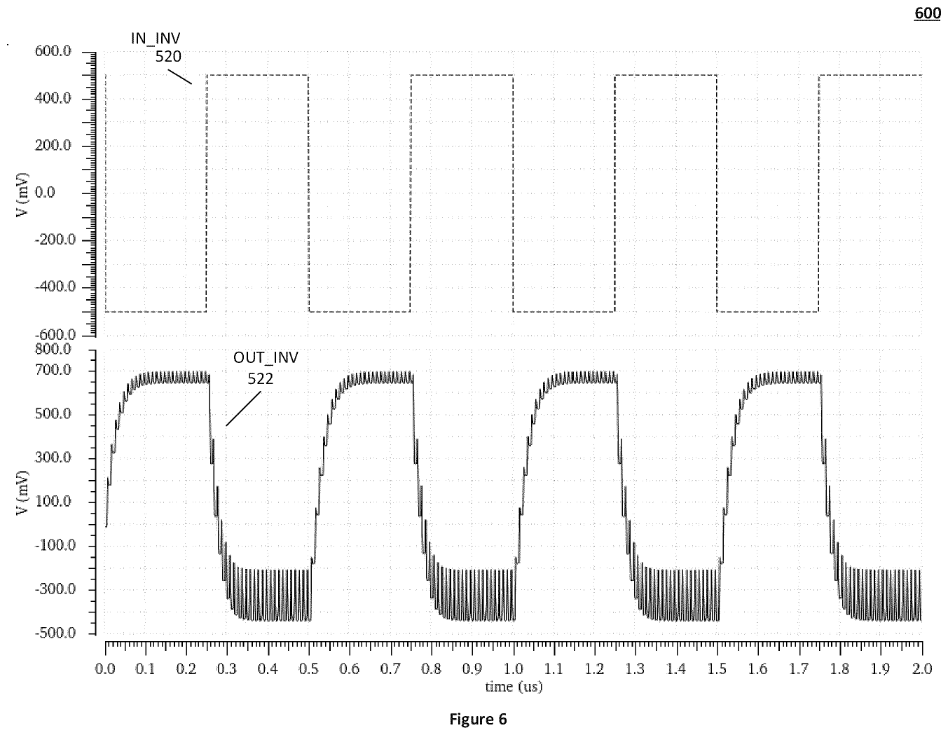

FIG. 6 shows the output OUT_INV 522 of inverter circuit 500 when input signal IN_INV 520 is applied.

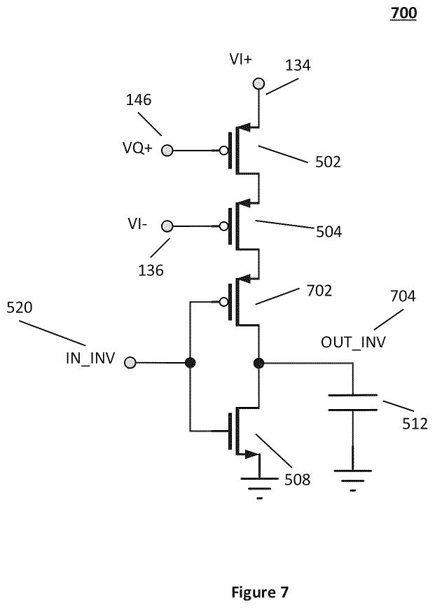

FIG. 7 shows an improved version of quadrature RF inverter 500 as a preferred embodiment of the invention. It is powered using three signals VI+ 134, VI− 136, and VQ+ 146 generated by the circuit of the embodiment of FIG. 1. In this embodiment, a PMOS transistor 702 is included in the PMOS charging branch and transistors 506 and 510 are eliminated. Transistor 702 allows the PMOS charging branch to conduct, and hence establish a positive charge on output capacitor 512, only if input signal 520 is low. This prevents output 704 from oscillating between high and low states when the input signal is high and also allows the removal of the sample and hold transistors 514 and 516 and capacitor 518. Furthermore, it also allows the circuit to operate well with only one isolation transistor 504. However, if lower power at higher voltages is required, transistor 506 can also be included to increase the branch's overall resistance at the expense of voltage headroom.

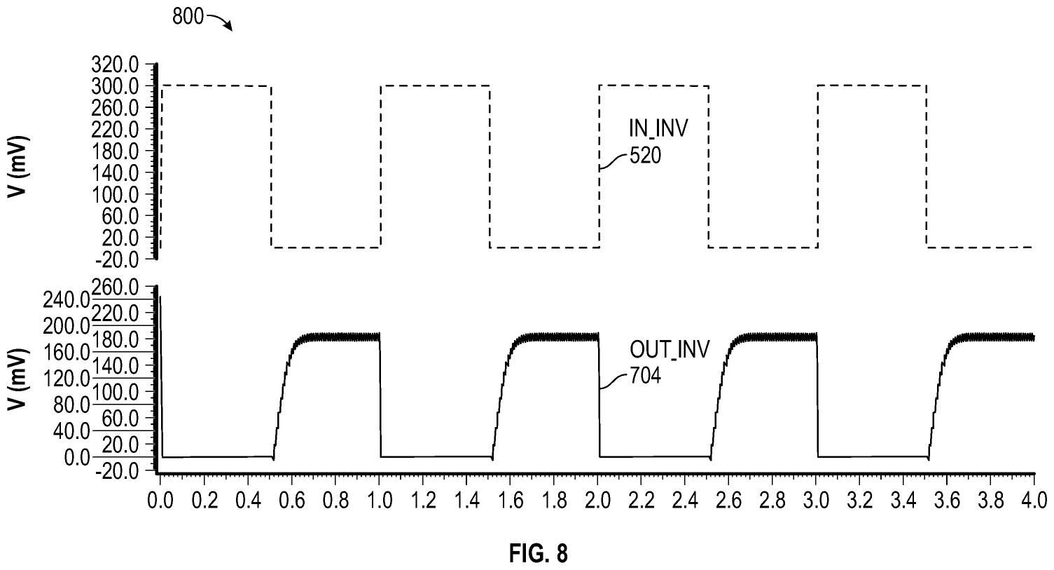

FIG. 8 shows output OUT_INV 704 of inverter circuit 700 with input signal IN_INV 520.

FIG. 9 shows another embodiment of the quadrature RF inverter circuit of FIG. 7. It is powered using two signals V+ 224 and V− 226 generated by the circuit of the embodiment of FIG. 2. The circuit's operation principle is similar to inverter circuit 700, except that this circuit only requires two 180° signals namely V+ 224 and V− 226. Hence transistor 502's gate signal VQ+ 146 is replaced by V− 226. This enables inverter 900 to evaluate logic in two phases 402 and 404. During pre-charge phase 402, transistors 502 and 504 switch ON. In this phase, depending on input 520, capacitor 512 may or may not charge. If there is a low (0) at input 520, transistor 702 switches ON and capacitor 512 charges to give a high (1) at output OUT_INV 902, whereas at input high (1) the charging branch remains OFF as transistor 702 stays off. In evaluate phase 404 the charging branch remains OFF and the logic is evaluated depending on input 520. If there is high (1) at input 520, transistor 508 provides a path to discharge capacitor 512 to the ground and it remains in cutoff region if there is a low at input 520.

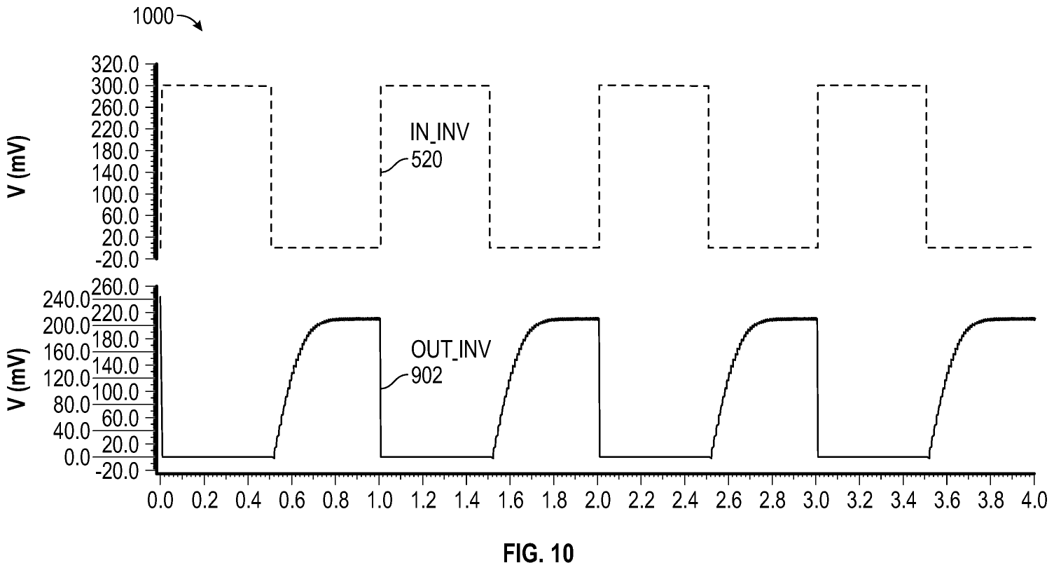

FIG. 10 shows output OUT_INV 902 of inverter circuit 900 with input signal IN_INV 520.

In other embodiments of the invention, the ground in discharging branch in invertor circuits 700 and 900 can be replaced by input signal VI+ 134 similar the one shown in embodiment of FIG. 5 to exploit the adiabatic nature of the logic. As a result, the power consumption is reduced.

In other embodiments of the invention, the inverter explained in the embodiment of FIGS. 5, 7 and 9 could be used as a buffer by using two inverters in series.

In other embodiments of the invention, the inverter circuits proposed can also be used to make ring oscillator by using odd number of inverter stages.

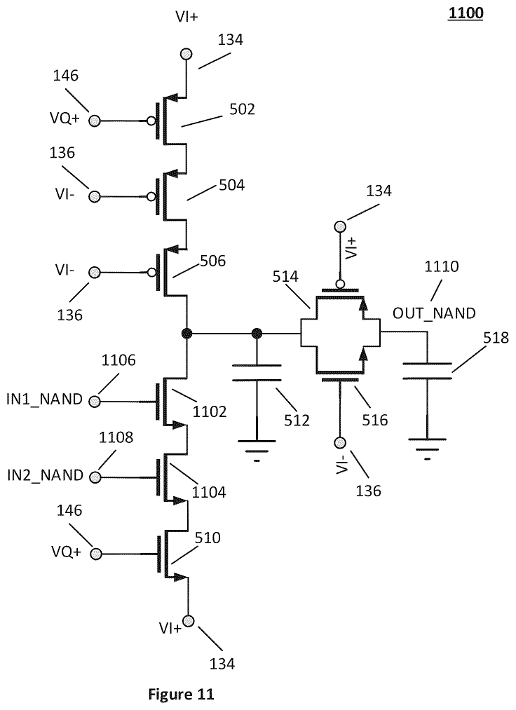

FIG. 11 shows an embodiment of the two input quadrature RF NAND gate powered by using three signals VI+ 134, VI− 136, and VQ+ 146 that are generated by the circuit of the embodiment of FIG. 1. The circuit's operation principle is similar to the inverter circuit of FIG. 5, except that inverting transistor 508 is now replaced by pair of transistors 1102 and 1104 placed in series, with input signals IN1_NAND 1106 and IN2_NAND 1108. The circuit's operation during the hold and pre-charge phases remains unchanged. During evaluation phase 306, two transistors 1102 and 1104 behave as a NAND gate and discharge output capacitor 512 through the NMOS branch only when both inputs are high (1), thereby fulfilling the requirement of NAND logic. The final output after the sample and hold is shown at capacitor 518 as OUT_NAND 1110.

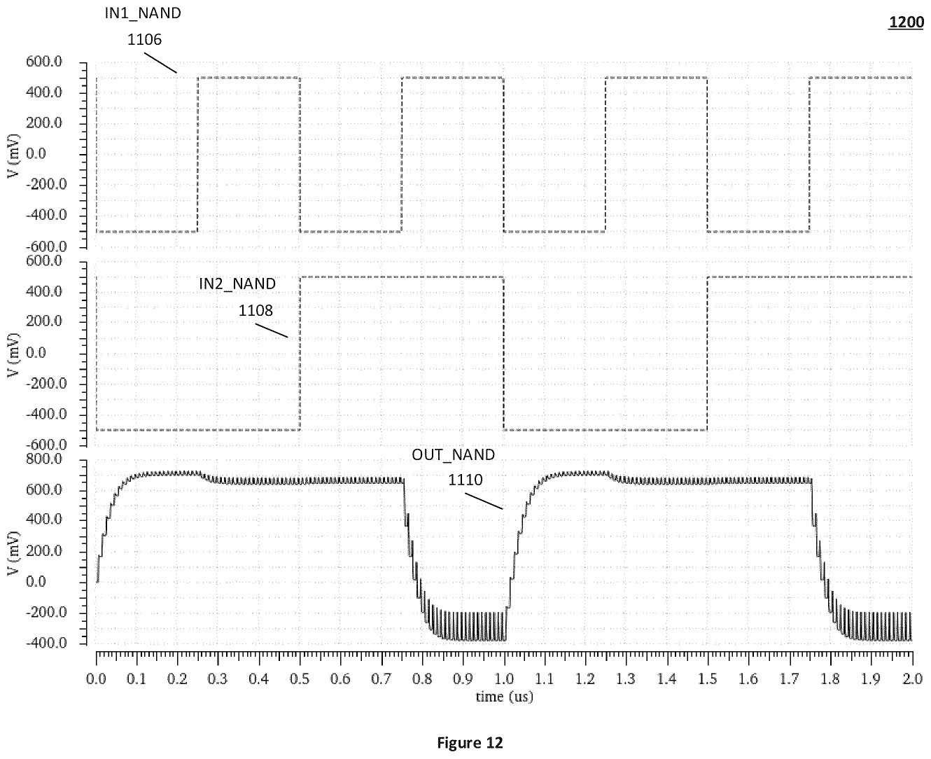

FIG. 12 shows output OUT_NAND 1110 of the NAND circuit 1100 with input signals IN1_NAND 1106 and IN2_NAND 1108.

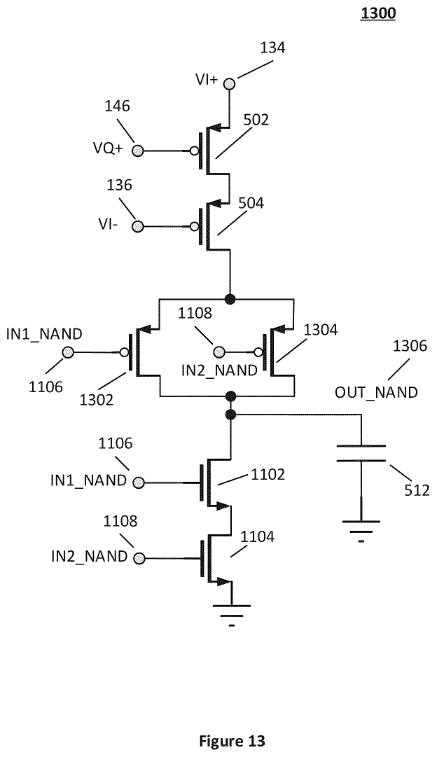

FIG. 13 shows an improved version of the two input quadrature RF NAND gate, that is a preferred embodiment built using the same principle as the inverter of the embodiment of FIG. 7, i.e. the circuit's operation principle is similar to that of inverter circuit 700. Parallel transistors 1302 and 1304 are combined with series transistors 1102 and 1104 that perform the NAND operation instead of the NOT operation in inverter circuit 700. In pre-charge phase 302, either of transistors 1302 and 1304 can conduct if any of inputs 1106 or 1108 is low (0), and this would charge capacitor 512, thereby establishing a positive voltage (high) at output OUT_NAND 1306. However, if neither of inputs 1106 or 1108 is low, two transistors 1302 and 1304 cut off the PMOS charging branch and prevent output capacitor 512 from going high. In evaluation phase 306, series NMOS transistors 1102 and 1104 conduct only if both of inputs 1006, 1008 are high. Thus circuit 1300 meets the definition of a NAND gate.

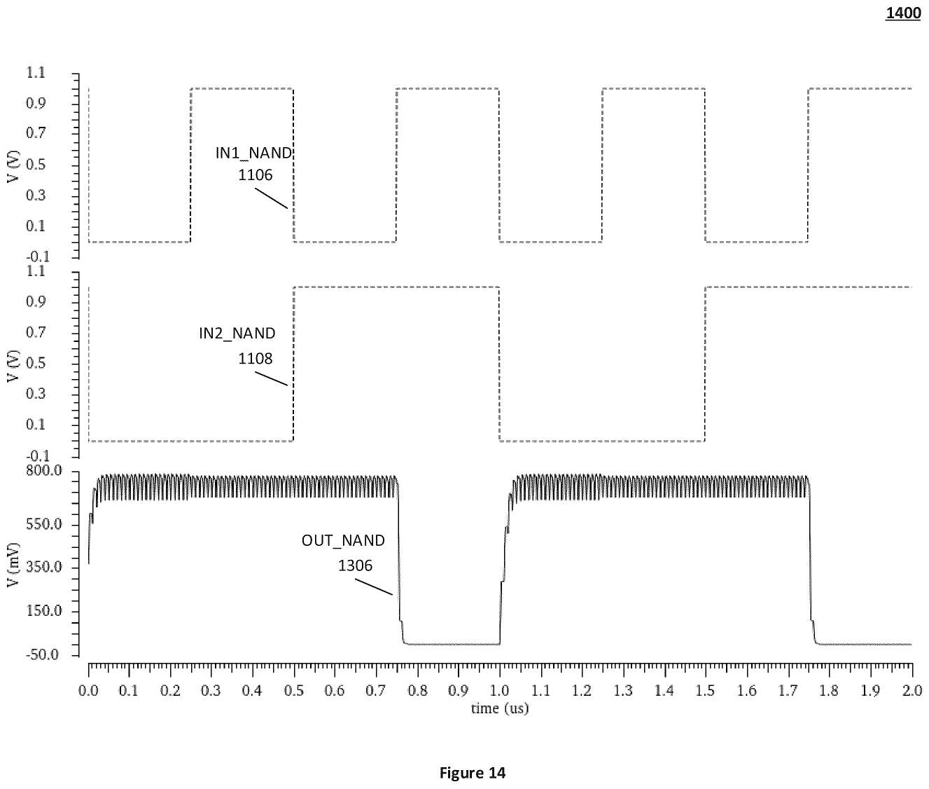

FIG. 14 shows output OUT_NAND 1306 of NAND circuit 1300 with input signals IN1_NAND 1106 and IN2_NAND 1108.

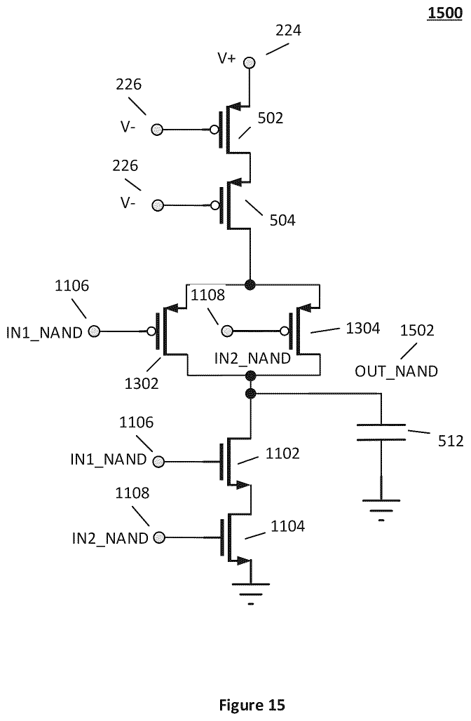

FIG. 15 shows another embodiment of the quadrature RF NAND gate. The circuit's operation principle is similar to NAND gate circuit 1300, except that this circuit only requires the two 180° signals V+ 224 and V− 226. Hence transistor 502's gate signal VQ+ 146 is replaced by V− 226. This enables the circuit to evaluate logic in two phases 402 and 404. During pre-charge phase 402, transistors 502 and 504 switch ON. In this phase, depending on input signals IN_NAND1 1106 and IN_NAND2 1108, capacitor 512 may or may not be charged. Either of transistors 1302 and 1304 can conduct if any of inputs 1106, 1108 is low, which would charge capacitor 512 and establish a positive voltage (high) at output 1502. However, if neither of inputs 1106, 1108 is low, two transistors 1302 and 1304 cut off the PMOS charging branch and prevent output capacitor 512 from going high. In evaluation phase 404, series NMOS transistors 1102 and 1104 conduct only if both of inputs 1106 and 1108 are high. Thus the circuit fulfills the definition of a NAND gate.

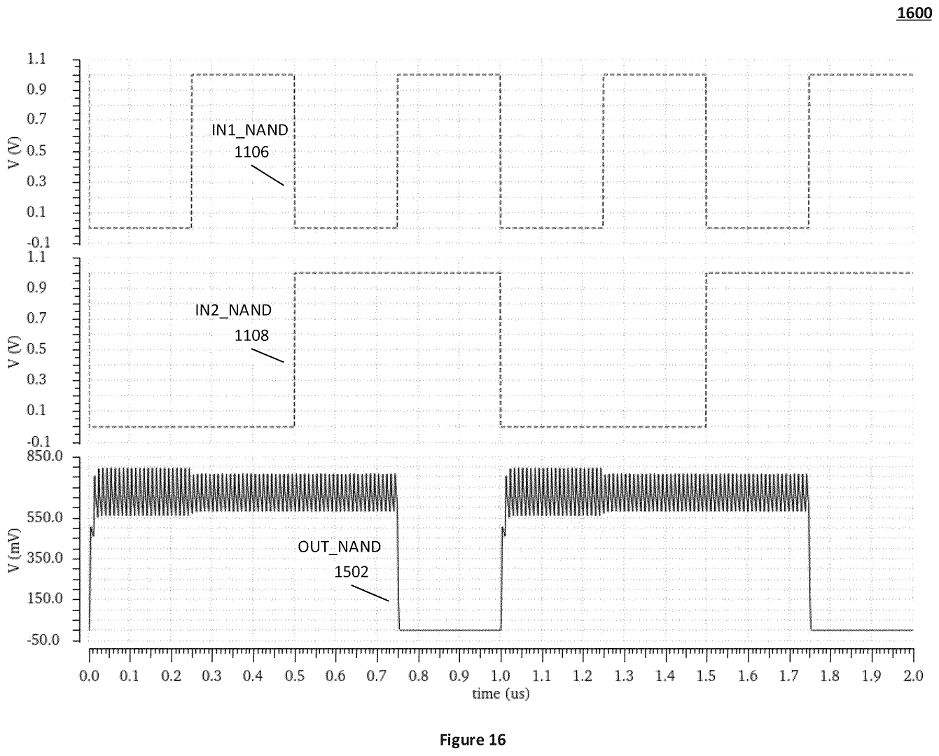

FIG. 16 shows output OUT_NAND 1502 of NAND circuit 1500 with input signals IN1_NAND 1106 and IN2_NAND 1108.

In other embodiments of the invention, the ground in discharging branch in circuits 1300 and 1500 can be replaced by the input signal VI+ 134 similar to the one shown in embodiment of FIG. 11 to exploit the adiabatic nature of the logic. As a result, the power consumption is reduced.

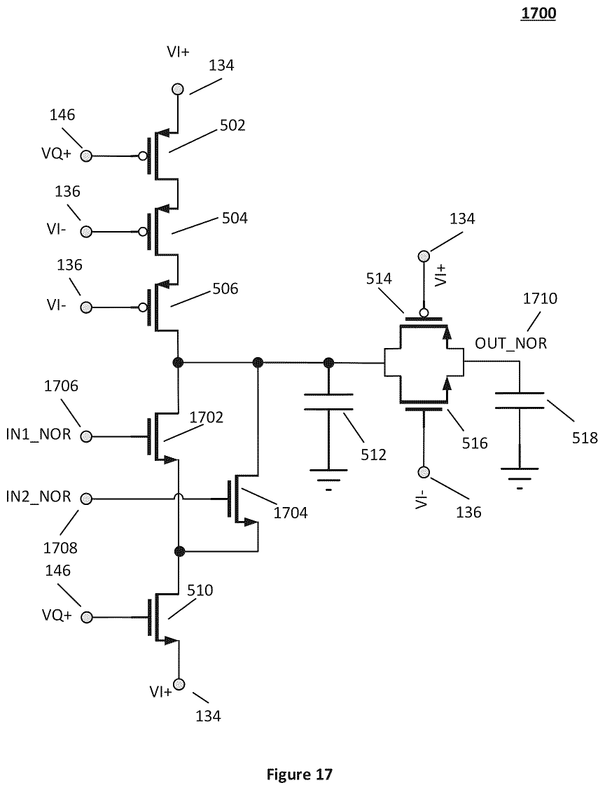

FIG. 17 shows an embodiment of the two-input quadrature RF NOR gate. Similar to the inverter circuit 500 and the NAND gate circuit 1100 of the embodiments of FIGS. 5 and 11, the circuit operates in four phases of the quadrature signals and is powered by three signals VI+ 134, VQ+ 146 and VI− 136. The PMOS charging branch initially charges output capacitor 512 irrespective of the inputs 1706 and 1708, whereas, the NMOS discharging branch conducts and discharges capacitor 512 using transistors 1702 or 1704 in case when the desired output is low, i.e., when either of inputs IN1_NOR 1706 or IN2_NOR 1708 is high. When the desired output is high, i.e., when both of inputs 1706 and 1708 signals are low, output OUT_NOR 1710 oscillates between high and low states similar to the previous circuits, and the problem is resolved using the sample and hold circuit comprising of transistors 514 and 516 and another output capacitor 518.

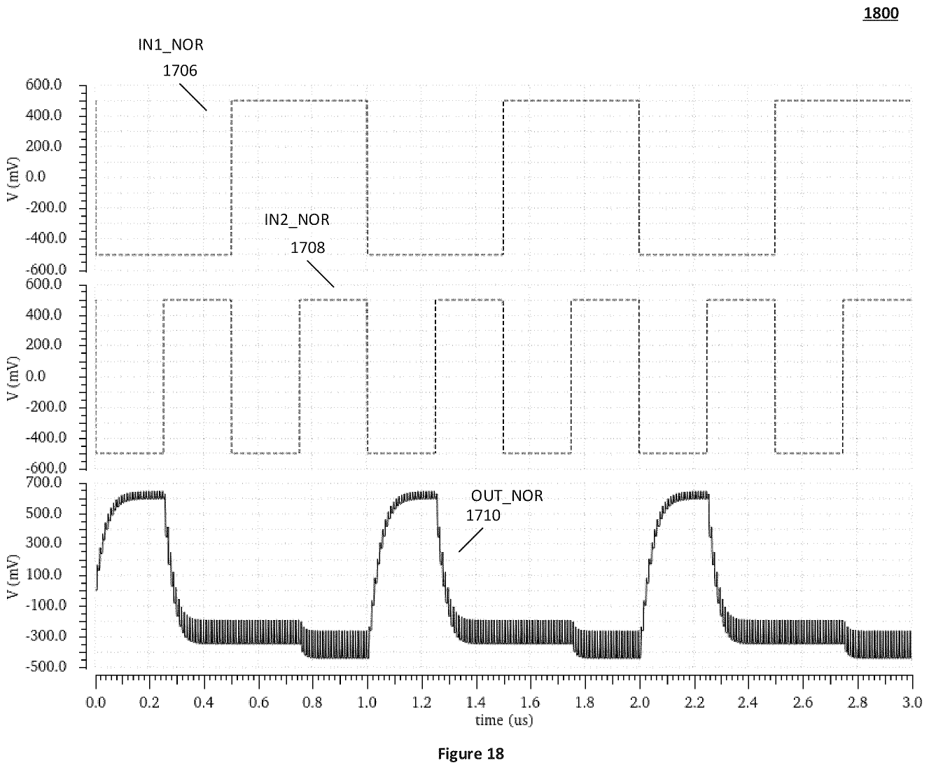

FIG. 18 shows output OUT_NOR 1710 of NOR circuit 1700 with input signals IN1_NOR 1706 and IN2_NOR 1708.

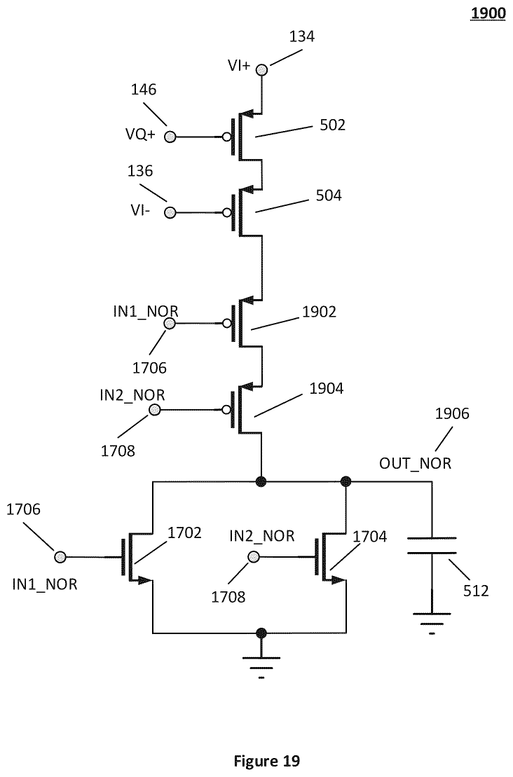

FIG. 19 shows an improved version of the two input quadrature RF NOR gate as the preferred embodiment of the invention. This version is also based on the same working principle as the two-input quadrature RF NAND gate of FIG. 13 except that in circuit 1900 PMOS transistor 1902 and 1904 are placed in series. Similar to the circuit 1300, the PMOS charging branch initially charges output capacitor 512 only in the case when the desired output is high, i.e., when both of inputs IN1_NOR 1706 and IN2_NOR 1708 are low due to the logic arrangement of PMOS transistors 1902 and 1904. NMOS transistors 1702 and 1704 in the discharging branch conduct and discharge output OUT_NOR 1906 from capacitor 512 in the case when the desired output is low, i.e., when either of the inputs is high. This is the definition of a NOR gate.

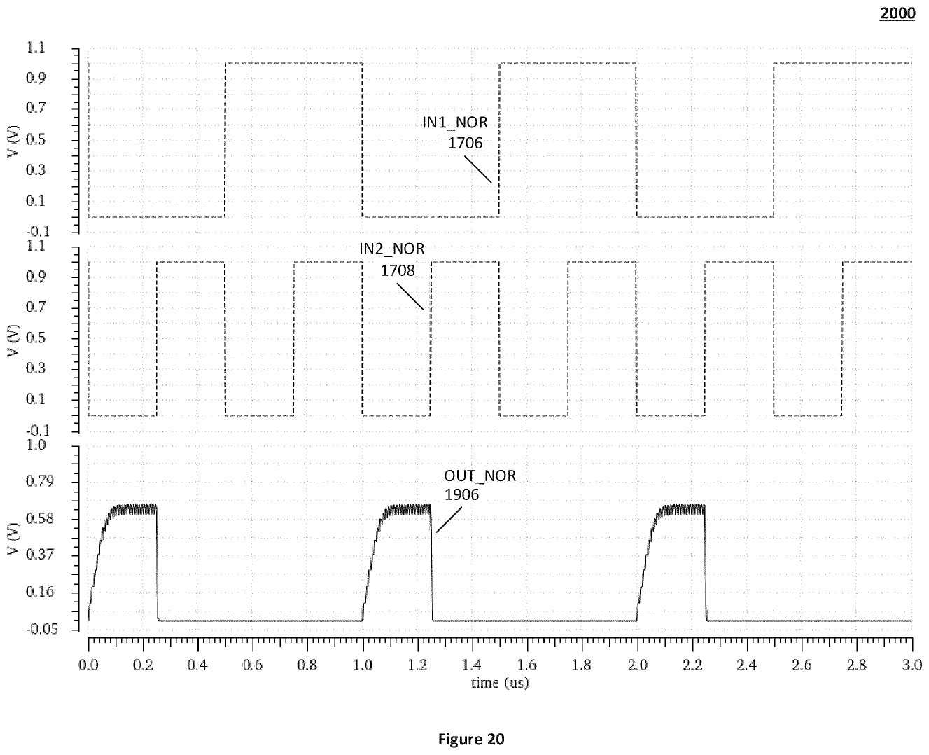

FIG. 20 shows output OUT_NOR 1906 of NOR circuit 1900 with input signals IN1_NOR 1706 and IN2_NOR 1708.

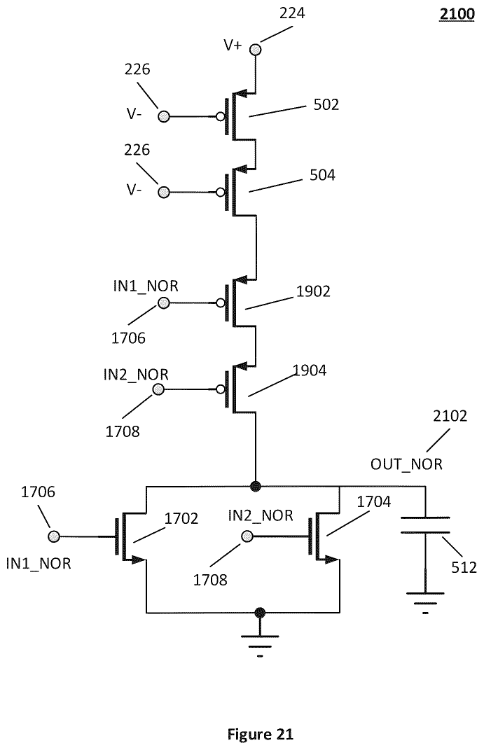

FIG. 21 shows another embodiment of the quadrature RF NOR gate. The circuit's operation principle is similar to the NAND gate circuit 1500. Similar to circuit 1500, the circuit only requires two 180° signals V+ 224 and V− 226, which enable the circuit to evaluate logic in two phases 402 and 404. During pre-charge phase 402, transistors 502 and 504 switch ON. In this phase, depending on the input signals IN1_NOR 1706 and IN2_NOR 1708, capacitor 512 may or may not charge. Transistors 1902 and 1904 can conduct only if both of the inputs are low, which charges capacitor 512 and sets a high at output 2102. However, if either of inputs 1706 or 1708 is high, the corresponding transistor cuts off the PMOS charging branch and prevents output capacitor 512 from going high. In evaluation phase 406, parallel NMOS transistors 1702 and 1704 conduct if any of two inputs 1706 or 1708 is high. Thus the circuit meets the definition of NOR gate.

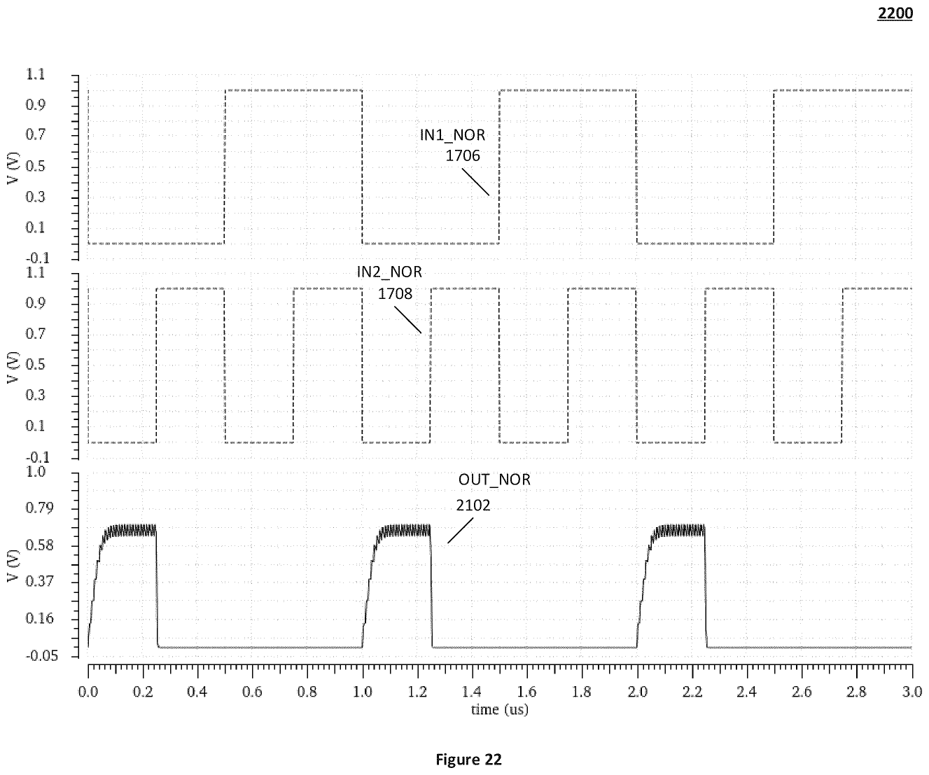

FIG. 22 shows output OUT_NOR 2102 of NOR circuit 2100 with input signals IN1_NOR 1706 and IN2_NOR 1708.

In other embodiments of the invention, the ground in discharging branch in circuits 1900 and 2100 can be replaced by the input signal VI+ 134 similar the one shown in embodiment of FIG. 17 to exploit the adiabatic nature of the logic. As a result, the power consumption is reduced.

In other embodiments of the invention, the NAND and NOR gate circuits can also include more than two inputs.

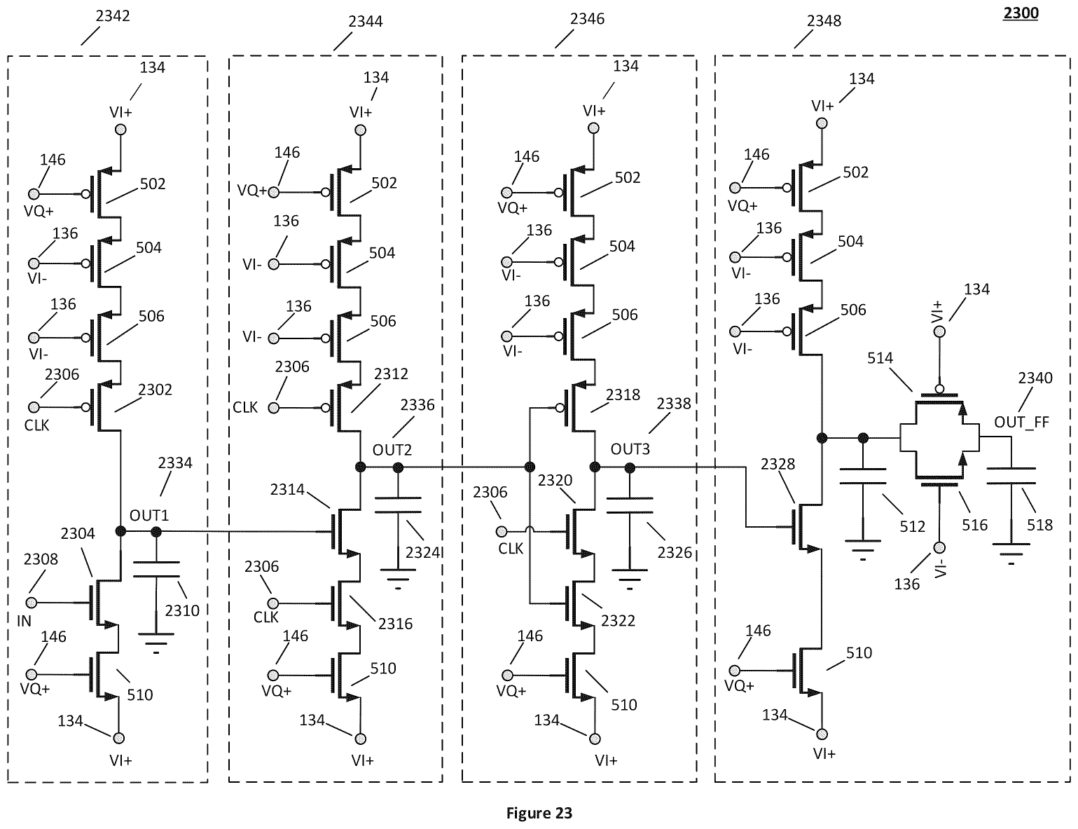

FIG. 23 shows an embodiment of a dynamic D Flip Flop based on the same principles as the inverter of the embodiment of FIG. 5. The circuit operates using three signals VI+ 134, VI− 136, and VQ+ 146 generated by the circuit of the embodiment of FIG. 1. The circuit can be divided into four stages 2342, 2344, 2346 and 2348, with each stage having two primary branches; the PMOS charging branch and the NMOS discharging branch. Four stages 2342, 2344, 2346 and 2348 are the same as in the conventional DC based dynamic D Flip Flop. To support operation with an AC supply, transistors 502, 504 and 506 are introduced and the gate to source signals of these transistors are arranged so as to ensure that only one branch conducts during each operating phase. Similar to the previous AC powered gates, transistors 504 and 506 in this embodiment are always ON due to the 180° nature of VI+ 134 and VI− 136 signals and are used for isolation to improve the circuit's operation. During pre-charge phase 302, when VI+ 134 is higher than VQ+ 146, transistors 502 conduct whereas 510 remains cutoff. Thus the AC supporting circuit allows all of the four PMOS branches to conduct during pre-charge phase 302 and the NMOS branches to conduct during evaluate phase 306. In order to uphold the operation of a D Flip Flop, circuit output 2340 must hold its previous value at both static states of the CLK signal 2306, i.e., at CLK=0 (low) and CLK=1 (high) and it must only change its output 2340 at the positive edge of CLK signal 2306. First examining the low static state (CLK=0), first stage 2342 is enabled in this state. So input signal IN 2308 propagates to node OUT1 2334 at capacitor 2310, i.e., if IN 2308 is low then output 2334 is pre-charged to high and if IN 2308 is high then output 2334 is discharged to low. However, second stage 2344 prevents it from going to next stages 2346 and 2348. This is because transistor 2316 is off which also disables 2314. Transistor 2312 is ON which pulls the node OUT2 2336 at capacitor 2324 up. So second stage 2338, irrespective of OUT1 2334 goes into a pre-charge state and pulls node OUT2 2336 up. This causes third stage 2346 to go into high impedance, since CLK=0 turns off 2320 and OUT2 (2336)=1 turns off 2318. Thus node OUT3 2338 holds its previous state. Now consider CLK=1 case. In this state, the first inverter's transistor 2302 is disabled, so only transistor 2304 is on. In the second inverter's transistor 2316 is on and transistor 2312 is off so transistor 2314 is enabled. In this state, either of the two inverters prevents the input signal from propagating depending on the value of input signal IN 2308. If IN=0, transistor 2304 turns off and stops the input. If IN=1, then transistor 2304 pulls 2334 to 0 and transistor 2314 turns off and prevents it from going further. Thus, in either case, node OUT2 2336 stays unchanged. Thus, the circuit cuts off the input in static states. Now for the negative edge of clock signal CLK 2306, i.e., when CLK goes from high to low. First stage 2342 is initially off and then it turns on. This allows signal IN 2308 to propagate to node 2334 after the edge. However, node 2336 goes from being connected to 2334 to the pre-charge state so it prevents the signal form going to the output, due to transistors 2312 and 2316. In the pre-charge state, node OUT2 2336 gets charged irrespective of input signal 2308. To isolate this from the output, third stage 2346 is used. This stage acts as a clock-controlled invertor, when CLK signal 2306 goes from high to low node OUT2 2336 gets high turning transistor 2322 ON and transistor 2318 OFF. As CLK signal 2306 is low, transistor 2320 stays OFF hence blocking OUT2 2336 node voltage. In the case of positive edge, i.e., CLK going from low to high. The PMOS branch of first stage 2342 goes from on to off. When it is on, this allows the initial state of signal IN 2308 to be loaded on node 2334 but then it gets disconnected. So node 2334 stores the momentary value of input 2308. Second stage 2344 goes from the pre-charge state to the discharge state. In this state, node 2336 stays high if stage 2334 is low and only goes low (discharges) if stage 2334 is high. Thus, node OUT2 2336 stores the actual value of IN 2308 while the node voltage at OUT3 2338 is inverted as CLK signal 2306 goes from low to high. Finally, last stage 2348 again inverts the signal at node OUT3 to store the momentary value of IN 2308 at final output OUT_FF 2340 on capacitor 518 and this meets the definition of a D Flip Flop.

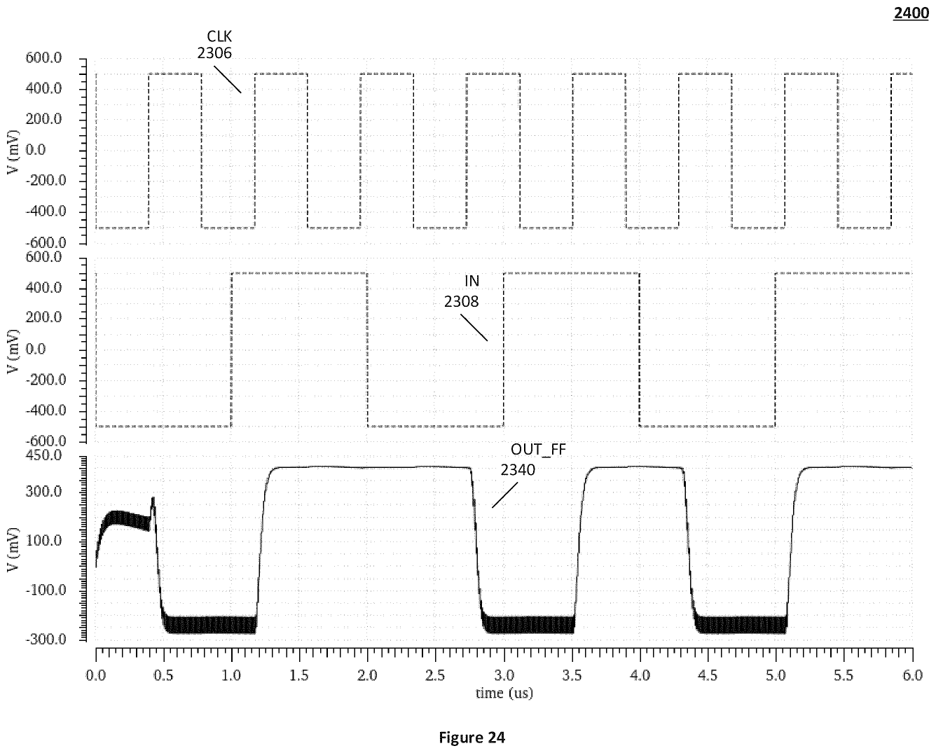

FIG. 24 shows output OUT_FF 2340 of Flip Flop circuit 2300 with input signal IN 2308 and CLK 2306.

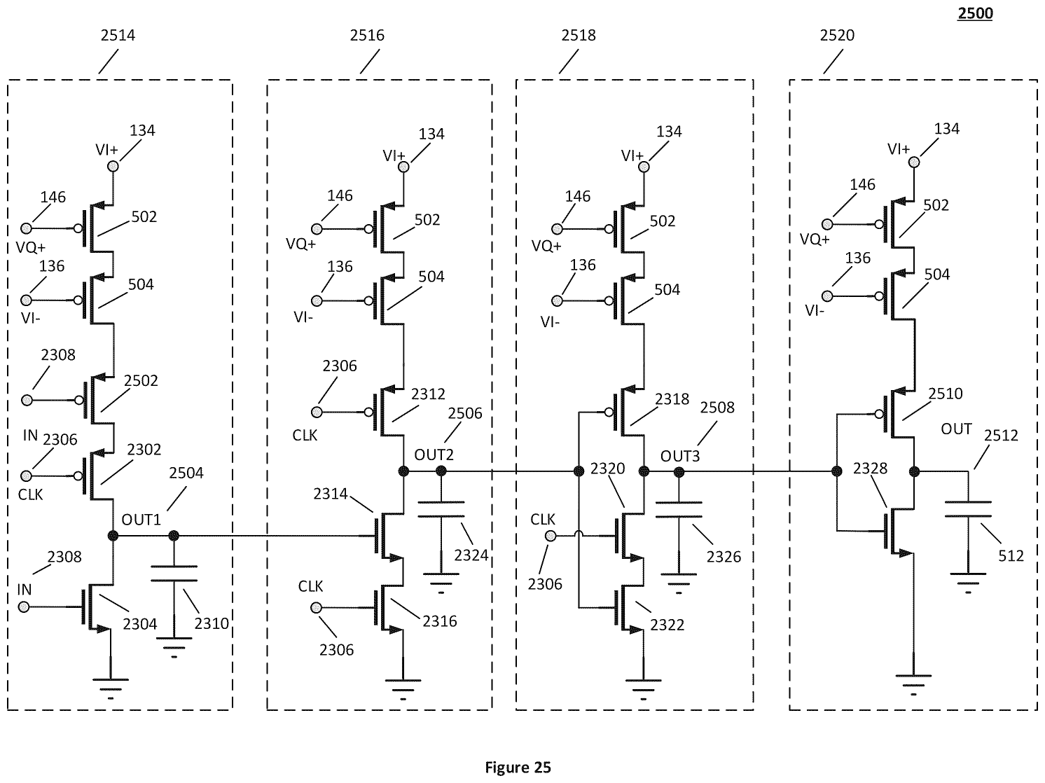

FIG. 25 shows an improved version of the Flip Flop circuit as the preferred embodiment of the invention. Similar to the previous modifications used in the preferred embodiments of FIGS. 7, 13 and 19, PMOS transistor 2502 is included in the charging branch of the first stage to only allow the charging of branch 2504 when supported by input signal 2308. This modification allows for the removal of one of isolation transistors 506 in all of the charging branches. All of NMOS transistors 510 in the discharging branches are also removed. PMOS transistor 2510 is also included in final inverting stage 2520. The output signals of branches 2514, 2516, 2518, and 2520 are established as OUT1 2504, OUT2 2506, OUT3 2508, and OUT_FF 2512 respectively at capacitors 2310, 2324, 2326 and 512. Sample and hold transistors 514, 516 and the corresponding capacitor 518 are also removed.

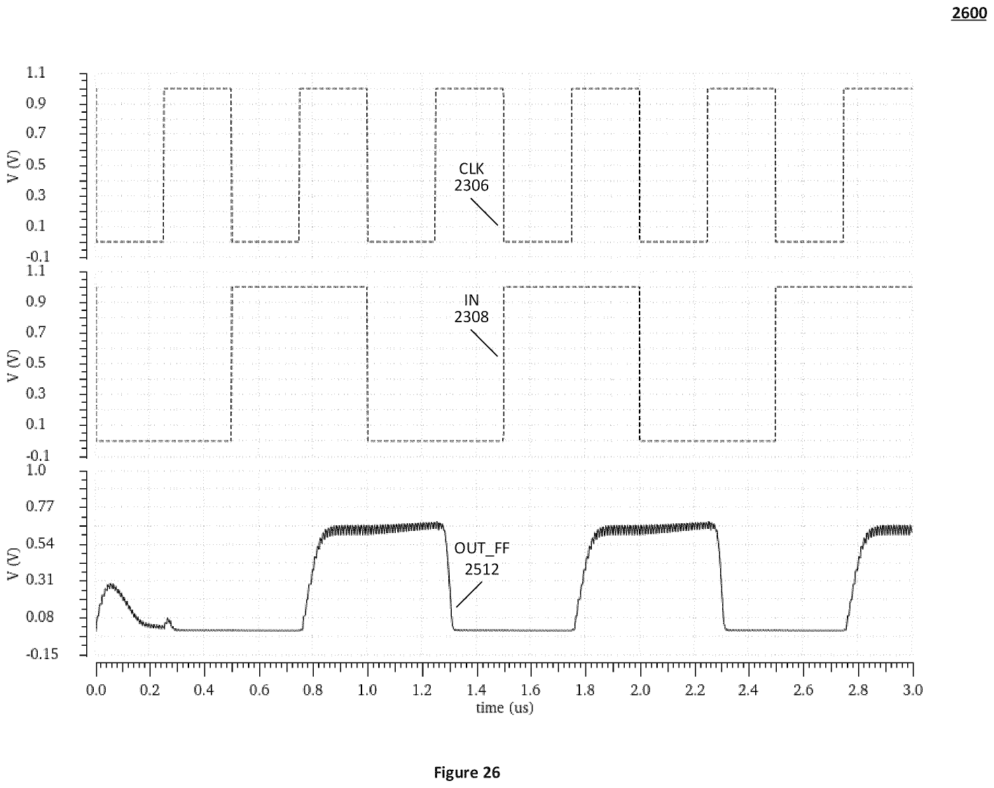

FIG. 26 shows output OUT_FF 2512 of D Flip Flop circuit 2500 with input signal IN 2308 and CLK 2306.

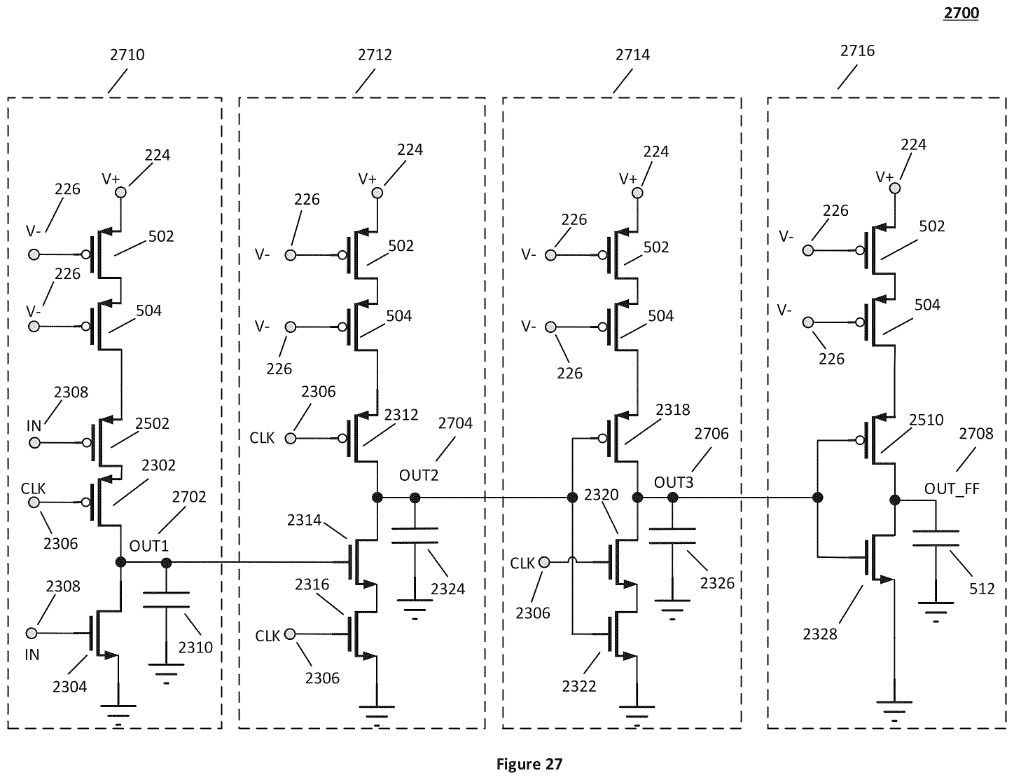

FIG. 27 shows another embodiment of the Dynamic D Flip Flop circuit powered by using two 180° signals V+ 224 and V− 226. Similar to the previous embodiments of FIGS. 9, 15 and 21, the circuit operates in two phases pre-charge phase 402 and evaluate phase 404. Rest of the working principle is same as described for circuit 2500 of the embodiment of FIG. 25. The outputs of stages 2710, 2712, 2714 and 2716 are shown as OUT1 2702, OUT2 2704, OUT3 2706 and OUT_FF 2708 respectively at capacitors 2310, 2324, 2326 and 512.

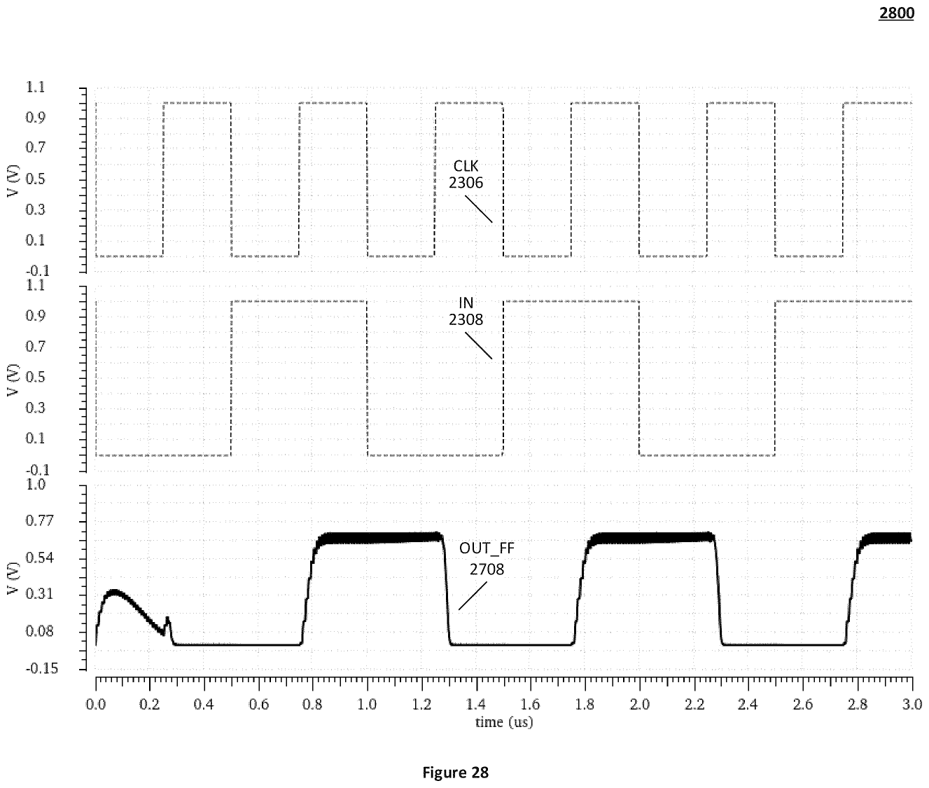

FIG. 28 shows output OUT_FF 2708 of D Flip Flop circuit 2700 with input signal IN 2308 and CLK 2306.

In other embodiments of the invention, the ground in discharging branch in circuits 2500 and 2700 can be replaced by the input signal VI+ 134 similar the one shown in embodiment of FIG. 23 to exploit the adiabatic nature of the logic.

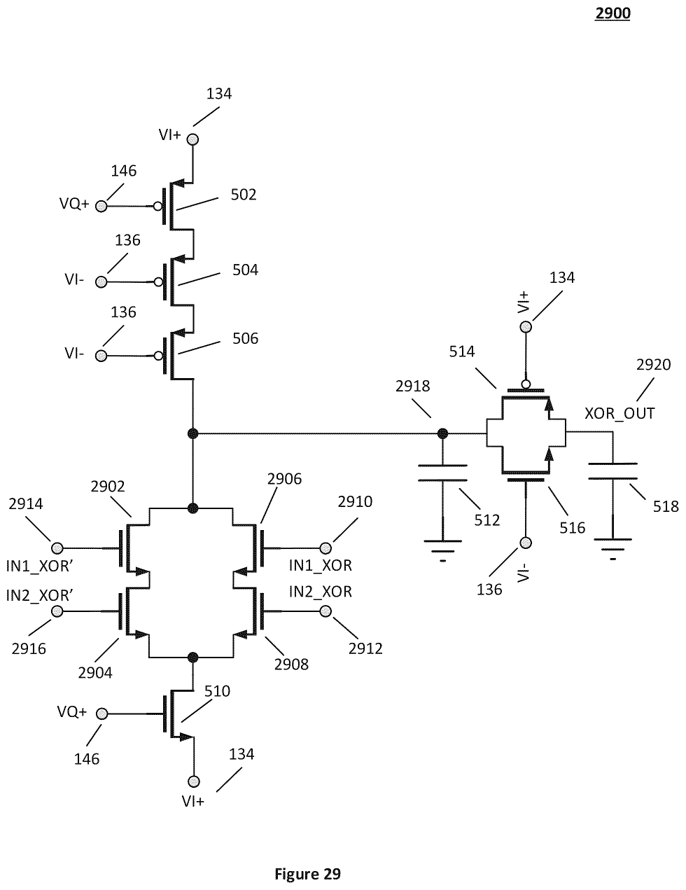

FIG. 29 shows the circuit of a two input XOR gate powered using three quadrature signals VI+ 134, VQ+ 146 and VI− 136. Similar to the previous embodiments, the PMOS charging branch charges node 2918 using the transistors 502, 504 and 506 during pre-charge phase 302 irrespective of the input. In evaluate phase 306, the NMOS discharging branch performs the XOR operation using transistors 2902, 2904, 2906 and 2908. The circuit uses two input signals IN1_XOR 2910 and IN2_XOR 2912 and their inverted versions IN1_XOR′ 2914 and IN2_XOR′ 2916 like a conventional XOR gate. Transistors 2902 and 2904 are placed in series with each other, thus forming the logic IN1_XOR NAND IN2_XOR, whereas transistors 2906 and 2908 are placed in series which makes the logic IN1_XOR′ NAND IN2_XOR′. The complete NMOS branch is the parallel of the two, which makes the desired XOR gate function. NMOS branch pulls output node 2918 down only when both inputs are negation of each other. Output 2918, similar to the previous embodiments, has the problem of oscillating between high and low states when expected output is high, and this happens when both inputs are same in a XOR gate. The problem is resolved using the sample and hold circuit comprising of transistors 514 and 516, and the final output is shown at capacitor 518 as XOR_OUT 2920.

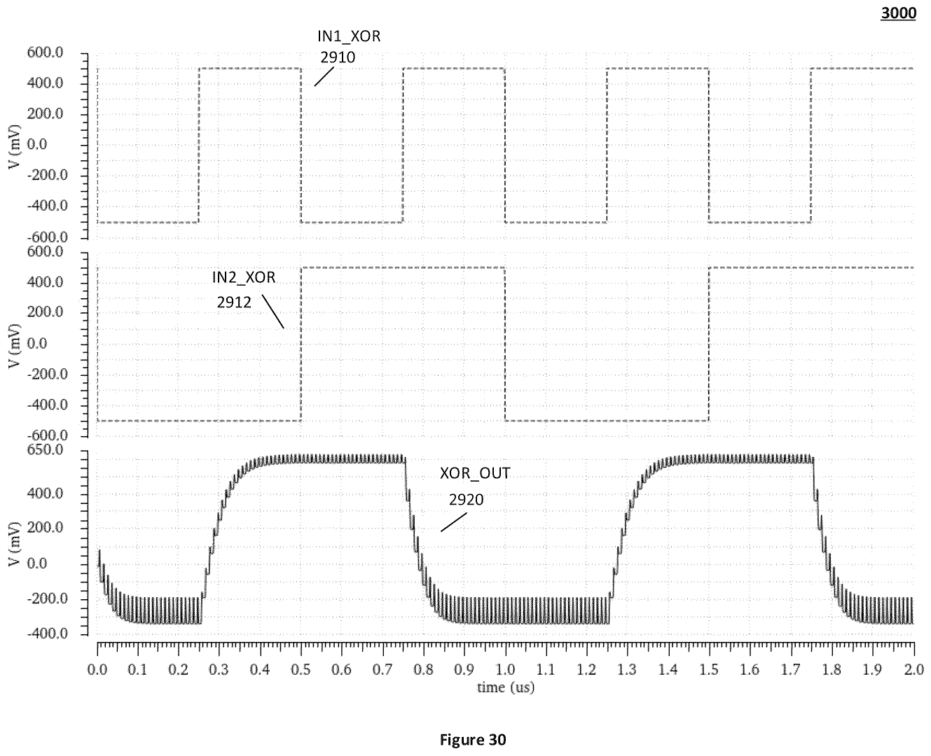

FIG. 30 shows output XOR_OUT 2920 of XOR circuit 2900 with input signals IN1_XOR 2910 and IN2_XOR 2912.

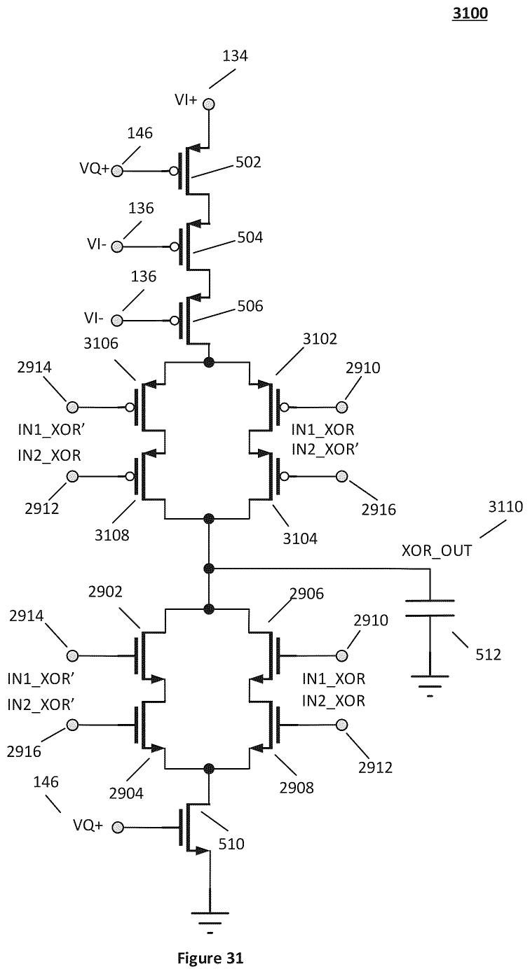

FIG. 31 shows an improved version of the two input quadrature XOR gate as the preferred embodiment of the invention. This version is also based on the same working principle as the two-input quadrature RF NAND gate of the embodiment of FIG. 13. Similar to circuit 1300, the PMOS charging branch initially charges output capacitor 512 only in the case when desired output 3110 is high, i.e., when both of inputs IN1_XOR 2910 and IN2_XOR 2912 are negation of one another, due to PMOS transistors 3102, 3104, 3106 and 3108 in the charging branch. These transistors are the complimentary logic equivalent of NMOS transistors 2902, 2904, 2906 and 2908 in the discharging branch.

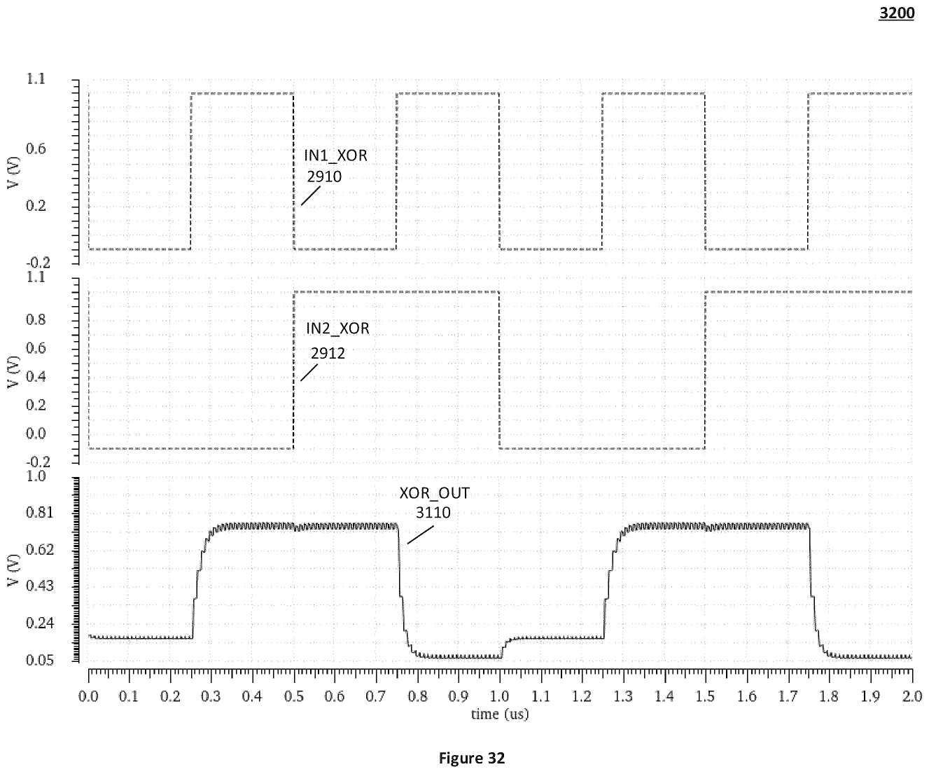

FIG. 32 shows output XOR_OUT 3110 of XOR circuit 3100 with input signals IN1_XOR 2910 and IN2_XOR 2912.

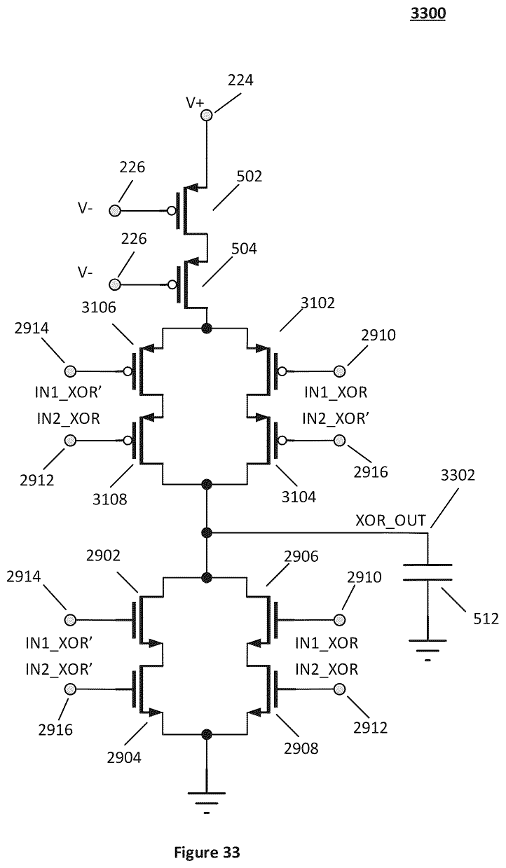

FIG. 33 shows another embodiment of the two input XOR gate powered using two 180° signals V+ 224 and V− 226. Similar to the previous embodiments of FIGS. 9, 15, 21 and 27, the circuit operates in the two phases, pre-charge phase 402 and evaluate phase 404, to get the desired output at XOR_OUT 3302. Rest of the working principle is same as described for the circuit 3100 of the embodiment of FIG. 31.

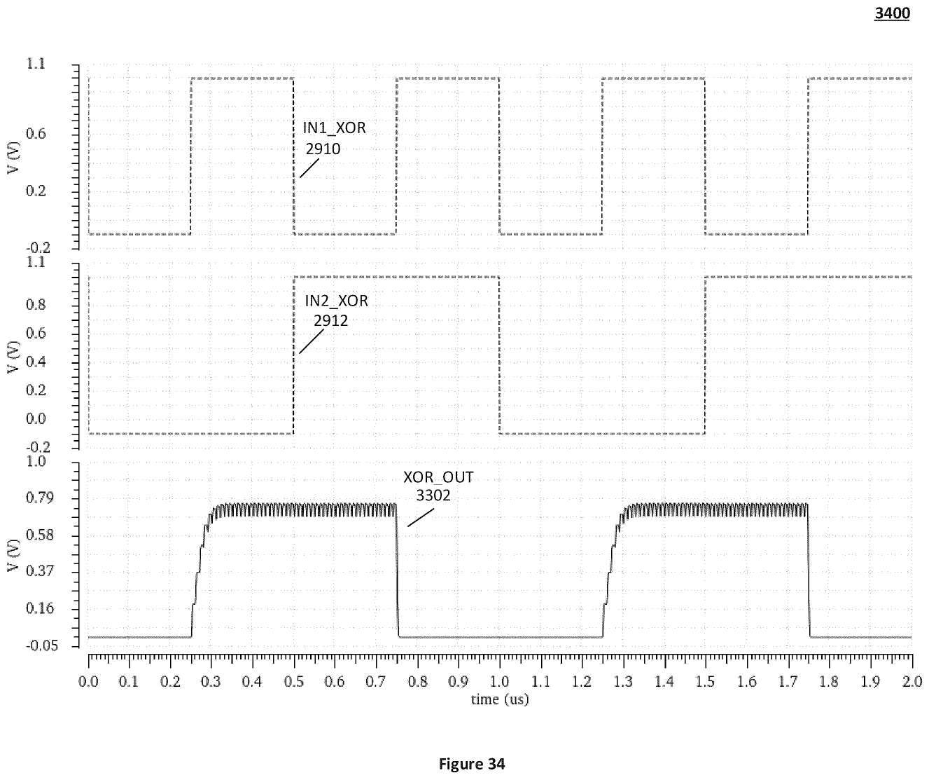

FIG. 34 shows output XOR_OUT 3302 of XOR circuit 3300 with input signals IN1_XOR 2910 and IN2_XOR 2912.

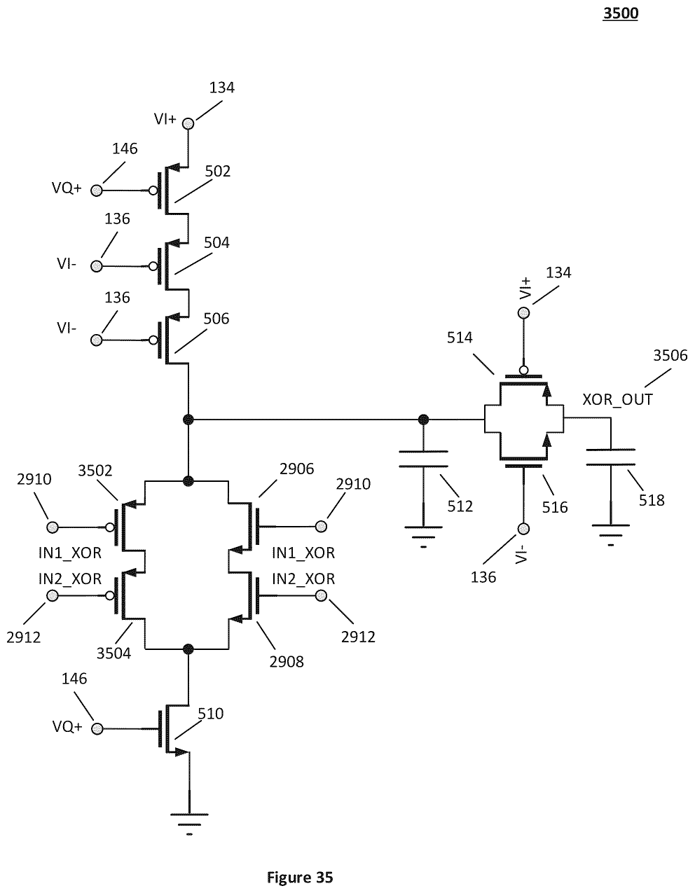

FIG. 35 shows another embodiment of circuit 2900 with a small modification. Circuit 2900 requires two input signals IN1_XOR 2910 and IN2_XOR 2912 as well as their complementary signals IN1_XOR′ 2914 and IN2_XOR′ 2916 for its proper function. This means that it also requires two inverters, not shown in the embodiment. This approach is desirable and is used as a standard in DC powered circuits due to its low static losses because both NMOS and PMOS transistors provide minimum resistance in their respective branches. However, in the case of AC powered circuits, especially when operated in the sub-threshold region, this benefit is insignificant since none of the transistors are expected to be providing the minimum resistance. This phenomenon can be leveraged to replace NMOS transistors 2902 and 2904 with inverted signals IN1_XOR′ 2914 and IN2_XOR′ 2916 in NMOS discharging branch with their PMOS counterparts 3502 and 3504, thus utilizing only input signals IN1_XOR 2910 and IN2_XOR 2912. This saves the two inverters required in the previous embodiment of FIG. 29.

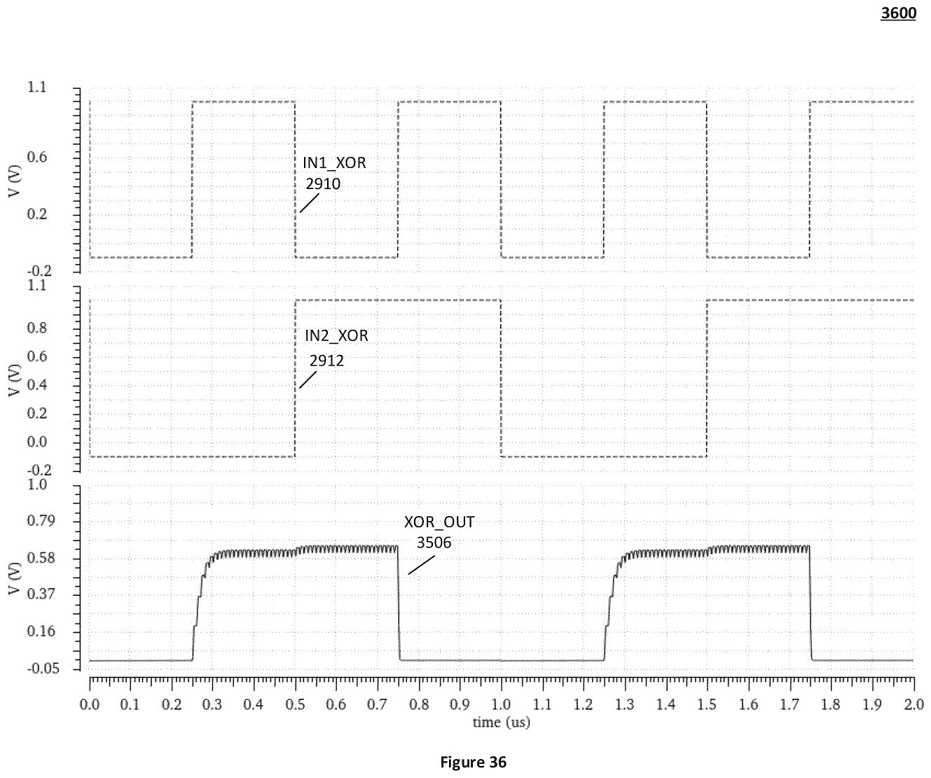

FIG. 36 shows output XOR_OUT 3506 of XOR circuit 3500 with input signals IN1_XOR 2910 and IN2_XOR 2912.

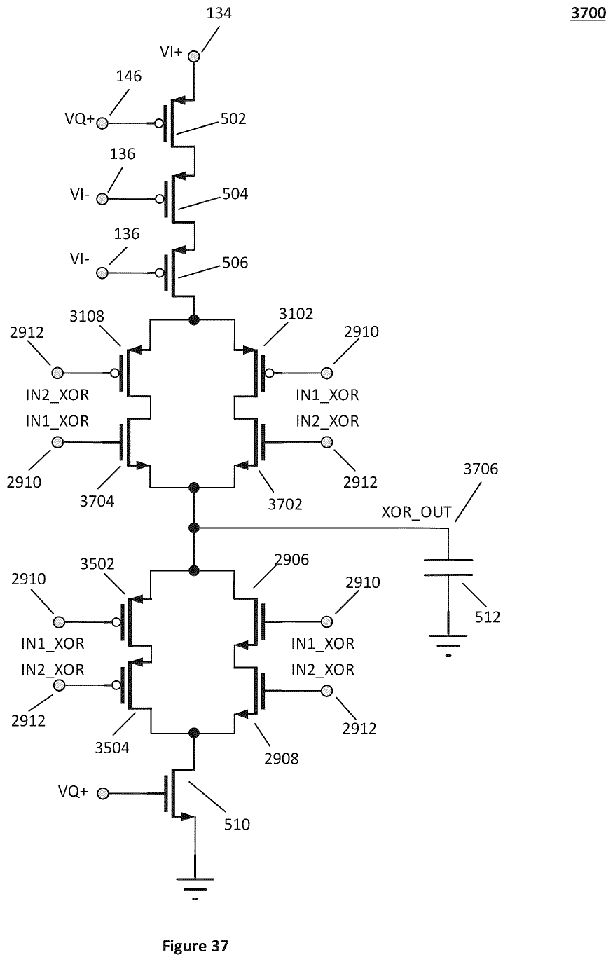

FIG. 37 shows another embodiment of the XOR gate of circuit 3100 with a small modification. Here NMOS transistors 2902 and 2904 in the discharging branch are replaced with PMOS transistors 3502 and 3504, and PMOS transistors 3104 and 3106 in the charging branch are replaced with NMOS transistors 3702 and 3704, thereby, eliminating the need for inverting the input signals.

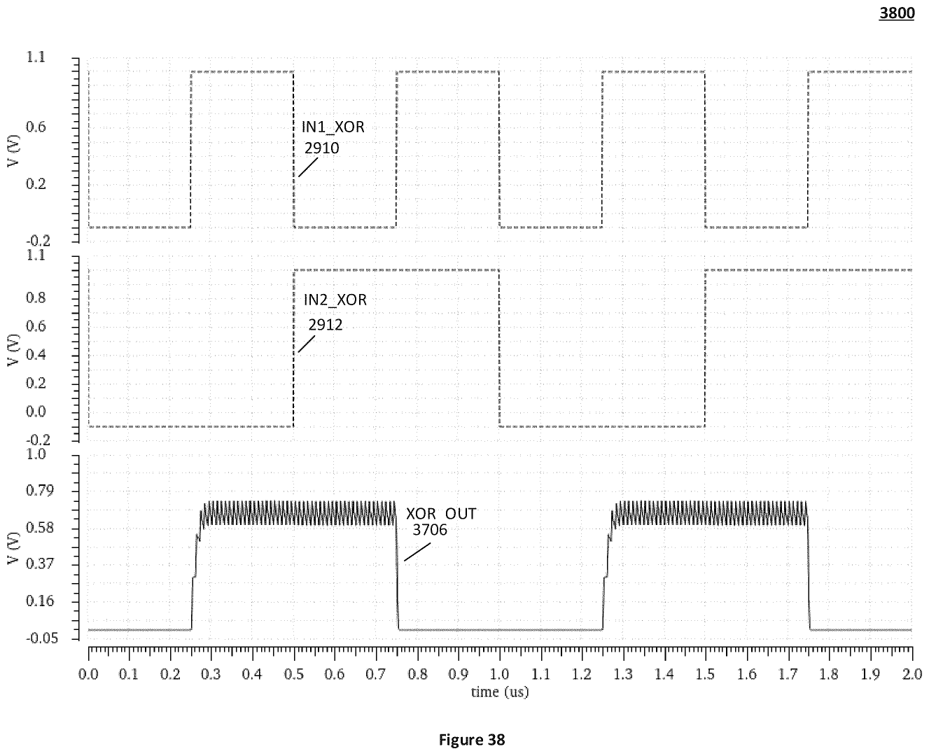

FIG. 38 shows output XOR_OUT 3706 of XOR circuit 3700 with input signals IN1_XOR 2910 and IN2_XOR 2912.

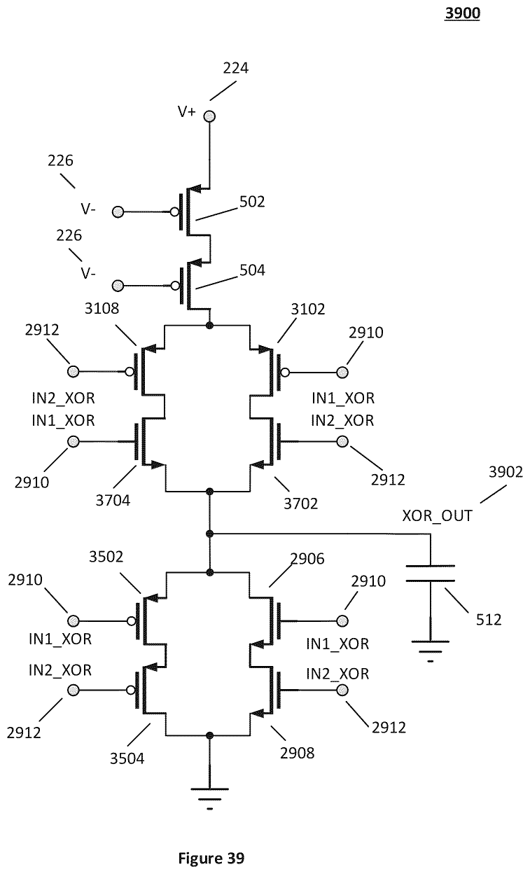

FIG. 39 shows another embodiment of XOR gate of circuit 3300 with a small modification. Here NMOS transistors 2902 and 2904 in the discharging branch are replaced with PMOS transistors 3502 and 3504, and PMOS transistors 3104 and 3106 in the charging branch are replaced with NMOS transistors 3702 and 3704, thereby, eliminating the need for inverting the input signals. The circuit operates in two phases, pre-charge phase 402 and evaluate phase 404, using only two 180° signals V+ 224 and V− 226.

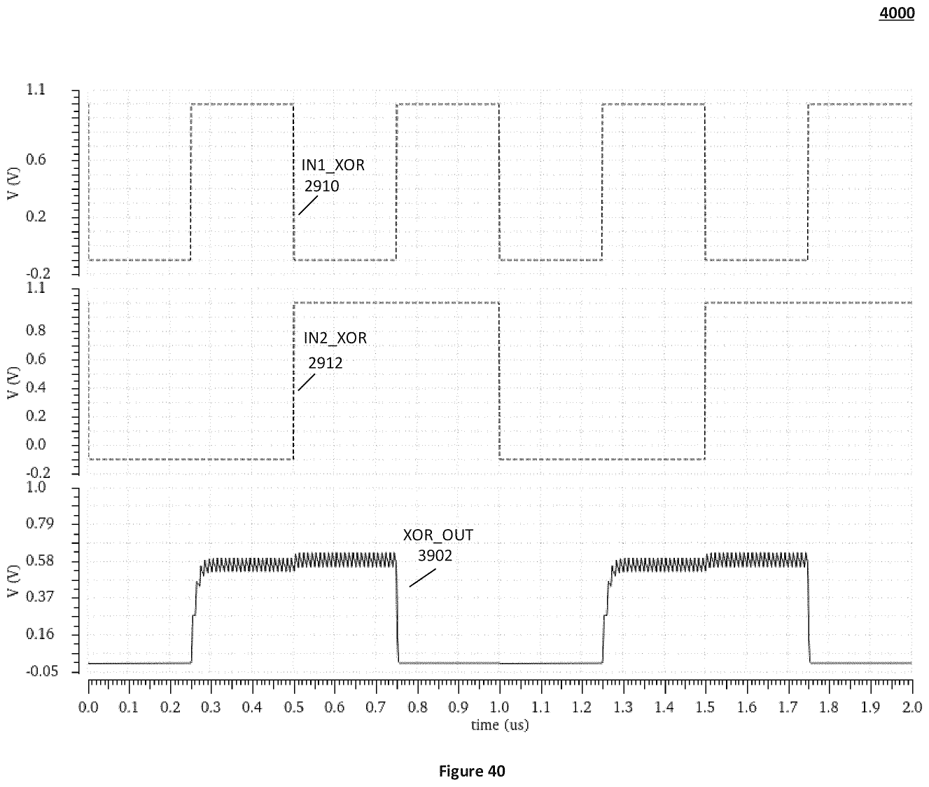

FIG. 40 shows output XOR_OUT 3902 of XOR circuit 3900 with e input signals IN1_XOR 2910 and IN2_XOR 2912.

In other embodiments of the invention, the ground in discharging branch in circuits 3100, 3300, 3500, 3700 and 3900 can be replaced by the input signal VI+ 134 similar the one as shown in embodiment of FIG. 29 to exploit the adiabatic nature of the logic. As a result, the power consumption is reduced.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of disclosed concept which is to be given the full breadth of the claims appended and any and all equivalents thereof.

What is claimed is:

1. An AC logic gate structured and configured to be powered by three or more AC signals, the three or more AC signals comprising three quadrature AC signals, wherein a complete cycle of the three quadrature AC signals has a plurality of phases, the AC logic gate comprising:
a plurality of transistors, each of a first one or more of the plurality of transistors being structured and configured to receive one or more of the three quadrature AC signals, and each of a second one or more of the plurality of transistors being structured and configured to receive one of a number of input signals; and
a capacitance coupled to the plurality of transistors, wherein the capacitance is structured and configured to be pre-charged responsive to a first one of the phases, wherein the capacitance is structured and configured to be discharged responsive to a second one of the phases, and wherein the AC logic gate is structured and configured to, responsive to the number of input signals, generate and output an output signal, wherein a state of the output signal depends on a state of each of the number of input signals.

2. The AC logic gate according to claim 1, wherein the three quadrature AC signals comprise a VI+ signal, a VI− signal, and a VQ+ signal, wherein the VI+ signal and the VI− signal are 180° out of phase with respect to one another, and wherein the VI+ signal and the VQ+ signal are 90° out of phase with respect to one another.

3. The AC logic gate according to claim 1, wherein the AC logic gate comprises an inverter, wherein the number of input signals is a single input signal, wherein the state of the output signal is an inverse of the state of the single input signal.

4. The AC logic gate according to claim 3, wherein the AC logic gate comprises a first branch and a second branch connected in series, wherein the first branch includes a first number of the first one or more of the plurality of transistors and the second branch includes the second one or more of the plurality of transistors and a second number of the first one or more of the plurality of transistors, wherein the capacitance is coupled to a point in between the first branch and the second branch, and wherein the AC logic gate is structured and configured such that during the first one of the phases only the first branch conducts and during the second one of the phases only the second branch conducts.

5. The AC logic gate according to claim 4, wherein each of the transistors of the first branch is a PMOS transistor and each of the transistors of the second branch is an NMOS transistor.

6. The AC logic gate according to claim 4, further comprising a sample and hold circuit coupled to the capacitance for sampling an output signal from the capacitance only during the second one of the phases, wherein an output of the sample and hold circuit is the output signal.

7. The AC logic gate according to claim 3, wherein the AC logic gate comprises a first branch and a second branch connected in series, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the AC logic gate is structured and configured such that the first branch only conducts responsive to the input signal being in a high state.

8. The AC logic gate according to claim 7, wherein each of the transistors of the first branch is a PMOS transistor and each of the transistors of the second branch is an NMOS transistor.

9. The AC logic gate according to claim 1, wherein the AC logic gate comprises a NAND gate, wherein the number of input signals is a first input signal and a second input signal, wherein the state of the output signal comprises a logical NAND of the state of the first input signal and the state of the second input signal.

10. The AC logic gate according to claim 9, wherein the AC logic gate comprises a first branch and a second branch connected in series, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal and a second transistor structured and configure to receive the second input signal, wherein the capacitance is coupled to a point in between the first branch and the second branch, and wherein the AC logic gate is structured and configured such that the first transistor and the second transistor operate as a NAND gate during the second one of the phases such that the capacitance is discharged only when the first input signal and the second input signal are high.

11. The AC logic gate according to claim 10, wherein each of the transistors of the first branch is a PMOS transistor and each of the transistors of the second branch is an NMOS transistor.

12. The AC logic gate according to claim 10, further comprising a sample and hold circuit coupled to the capacitance for sampling an output signal from the capacitance only during the second one of the phases, wherein an output of the sample and hold circuit is the output signal.

13. The AC logic gate according to claim 9, wherein the AC logic gate comprises a first branch and a second branch connected in series, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the first number of the second one or more of the plurality of transistors comprises a first transistor structured and configure to receive the first input signal and a second transistor structured and configure to receive the second input signal, and the second number of the second one or more of the plurality of transistors comprises a third transistor structured and configure to receive the first input signal and a fourth transistor structured and configure to receive the second input signal.

14. The AC logic gate according to claim 13, wherein the first transistor and the second transistor are connected in parallel to one another.

15. The AC logic gate according to claim 13, wherein each of the transistors of the first branch is a PMOS transistor and each of the transistors of the second branch is an NMOS transistor.

16. The AC logic gate according to claim 1, wherein the AC logic gate comprises a NOR gate, wherein the number of input signals is a first input signal and a second input signal, wherein the state of the output signal comprises a logical NOR of the state of the first input signal and the state of the second input signal.

17. The AC logic gate according to claim 16, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal and a second transistor structured and configure to receive the second input signal, wherein the capacitance is coupled to a point in between the first branch and the second branch, and wherein the AC logic gate is structured and configured such that the first transistor and the second transistor operate as a NOR gate during the second one of the phases such that the capacitance is discharged only when at least one of the first input signal and the second input signal is high.

18. The AC logic gate according to claim 17, wherein each of the transistors of the first branch is a PMOS transistor and each of the transistors of the second branch is an NMOS transistor.

19. The AC logic gate according to claim 17, further comprising a sample and hold circuit coupled to the capacitance for sampling an output signal from the capacitance only during the second one of the phases, wherein an output of the sample and hold circuit is the output signal.

20. The AC logic gate according to claim 16, wherein the AC logic gate comprises a first branch and a second branch, wherein the first branch includes a first number of the first one or more of the plurality of transistors and a first number of the second one or more of the plurality of transistors and the second branch includes a second number of the second one or more of the plurality of transistors, wherein the capacitance is coupled to a point in between the first branch and the second branch, wherein the first number of the second one or more of the plurality of transistors comprises a first transistor structured and configure to receive the first input signal and a second transistor structured and configure to receive the second input signal, and the second number of the second one or more of the plurality of transistors comprises a third transistor structured and configure to receive the first input signal and a fourth transistor structured and configure to receive the second input signal.

21. The AC logic gate according to claim 20, wherein the third transistor and the fourth transistor are connected in parallel to one another.

22. The AC logic gate according to claim 20, wherein each of the transistors of the first branch is a PMOS transistor and each of the transistors of the second branch is an NMOS transistor.

23. The AC logic gate according to claim 1, wherein the AC logic gate comprises an XOR gate, wherein the number of input signals is a first input signal and a second input signal, wherein the state of the output signal comprises a logical NOR of the state of the first input signal and the state of the second input signal.

24. The AC logic gate according to claim 23, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive a compliment of the first input signal, a second transistor structured and configure to receive a compliment of the second input signal, a third transistor structured and configure to receive the first input signal, a fourth transistor structured and configure to receive the second input signal, wherein the capacitance is coupled to a point in between the first branch and the second branch, wherein the first and second transistors are connected in series with each other and the third and fourth transistors are connection in series with each other, and wherein the first and second transistors are connected in parallel with the third and fourth transistors.

25. The AC logic gate according to claim 24, wherein each of the transistors of the first branch is a PMOS transistor and each of the transistors of the second branch is an NMOS transistor.

26. The AC logic gate according to claim 24, further comprising a sample and hold circuit coupled to the capacitance for sampling an output signal from the capacitance only during the second one of the phases, wherein an output of the sample and hold circuit is the output signal.

27. The AC logic gate according to claim 23, wherein the AC logic gate comprises a first branch and a second branch, wherein the first branch includes a first number of the first one or more of the plurality of transistors and a first number of the second one or more of the plurality of transistors and the second branch includes a second number of the first one or more of the plurality of transistors and a second number of the second one or more of the plurality of transistors, wherein the first number of the second one or more of the plurality of transistors includes a first transistor structured and configure to receive a compliment of the first input signal, a second transistor structured and configure to receive the second input signal, a third transistor structured and configure to receive the first input signal, a fourth transistor structured and configure to receive a compliment of the second input signal, wherein the second number of the second one or more of the plurality of transistors includes a fifth transistor structured and configure to receive a compliment of the first input signal, a sixth transistor structured and configure to receive a compliment of the second input signal, a seventh transistor structured and configure to receive the first input signal, an eighth transistor structured and configure to receive the second input signal, wherein the capacitance is coupled to a point in between the first branch and the second branch, wherein the first and second transistor are connected in series with each other and the third and fourth transistors are connection in series with each other, and wherein the first and second transistor are connected in parallel with the third and fourth transistor, and wherein the fifth and sixth transistors are connected in series with each other and the seventh and eighth transistors are connection in series with each other, and wherein the fifth and sixth transistors are connected in parallel with the seventh and eighth transistors.

28. The AC logic gate according to claim 27, wherein each of the transistors of the first branch is a PMOS transistor and each of the transistors of the second branch is an NMOS transistor.

29. The AC logic gate according to claim 23, wherein the AC logic gate comprises a first branch and a second branch, wherein the first branch includes a first number of the first one or more of the plurality of transistors and the second branch includes the second one or more of the plurality of transistors and a second number of the first one or more of the plurality of transistors, wherein the second one or more of the plurality of transistors includes a first transistor structured and configure to receive the first input signal, a second transistor structured and configure to receive the second input signal, a third transistor structured and configure to receive the first input signal, a fourth transistor structured and configure to receive the second input signal, wherein the capacitance is coupled to a point in between the first branch and the second branch, wherein the first and second transistors are connected in series with each other and the third and fourth transistors are connection in series with each other, and wherein the first and second transistors are connected in parallel with the third and fourth transistors.

30. The AC logic gate according to claim 29, wherein each of the transistors of the first branch is a PMOS transistor and each of the transistors of the second branch is an NMOS transistor.

31. The AC logic gate according to claim 29, further comprising a sample and hold circuit coupled to the capacitance for sampling an output signal from the capacitance only during the second one of the phases, wherein an output of the sample and hold circuit is the output signal.

32. The AC logic gate according to claim 23, wherein the AC logic gate comprises a first branch and a second branch, wherein the first branch includes a first number of the first one or more of the plurality of transistors and a first number of the second one or more of the plurality of transistors and the second branch includes a second number of the first one or more of the plurality of transistors and a second number of the second one or more of the plurality of transistors, wherein the first number of the second one or more of the plurality of transistors includes a first transistor structured and configure to receive the second input signal, a second transistor structured and configure to receive the first input signal, a third transistor structured and configure to receive the first input signal, a fourth transistor structured and configure to receive the second input signal, wherein the second number of the second one or more of the plurality of transistors includes a fifth transistor structured and configure to receive the first input signal, a sixth transistor structured and configure to receive the second input signal, a seventh transistor structured and configure to receive the first input signal, an eighth transistor structured and configure to receive the second input signal, wherein the capacitance is coupled to a point in between the first branch and the second branch, wherein the first and second transistor are connected in series with each other and the third and fourth transistors are connection in series with each other, and wherein the first and second transistor are connected in parallel with the third and fourth transistor, and wherein the fifth and sixth transistors are connected in series with each other and the seventh and eighth transistors are connection in series with each other, and wherein the fifth and sixth transistors are connected in parallel with the seventh and eighth transistors.

33. The AC logic gate according to claim 32, wherein each of the transistors of the first branch is a PMOS transistor and each of the transistors of the second branch is an NMOS transistor.

34. A method of performing digital logic operations, comprising:
receiving three quadrature AC signals in a transistor circuit of an AC logic gate to power the AC logic gate, wherein a complete cycle of the three quadrature AC signals has a plurality of phases;
receiving a number of input signals in the transistor circuit;
pre-charging a capacitance of the AC logic gate responsive to a first one of the phases, the capacitance being coupled to the transistor circuit;
discharging the capacitance responsive to a second one of the phases; and
responsive to the number of input signals, generating and outputting an output signal from the AC logic gate, wherein a state of the output signal depends on a state of each of the number of input signals.

35. The method according to claim 34, wherein the three quadrature AC signals comprise a VI+ signal, a VI− signal, and a VQ+ signal, wherein the VI+ signal and the VI− signal are 180° out of phase with respect to one another, and wherein the VI+ signal and the VQ+ signal are 90° out of phase with respect to one another.
